(19) United States
(12) Patent Application Publication
(10) Pub. No.: US 2026/0271530 A1
(43) Pub. Date: Sep. 10, 2026

(54) DISPLAY DEVICE AND METHOD FOR MANUFACTURING DISPLAY DEVICE

(71) Applicant: Sharp Display Technology Corporation, Kameyama City, Mie (JP)

(72) Inventor: Masayuki KANEHIRO, Kameyama City (JP)

(21) Appl. No.: 19/162,089

(22) PCT Filed: Mar. 8, 2023
(86) PCT No.: PCT/JP2023/008902

§ 371 Date: Sep. 4, 2025

(51) Int. Cl. H10K 59/122; H10K 50/115; H10K 59/12; H10K 59/35

(52) U.S. Cl. CPC H10K 59/122; H10K 59/1201; H10K 59/353; H10K 50/115

(57) ABSTRACT

A quantum-dot display device includes a plurality of quantum-dot light-emitting elements each having a light-emitting layer individually separated. A display region is provided with a dividing layer having a plurality of openings corresponding to subpixels. An inner peripheral surface of each opening of the dividing layer is formed to have a reverse-tapered angled surface so that the opening widens downwards of the dividing layer. The light-emitting layer is provided inside the opening of the dividing layer.

### TECHNICAL FIELD

The present disclosure relates to a display device, and a method for manufacturing the display device.

### BACKGROUND ART

In recent years, self-luminous display devices have been under development and practical application. Known self-luminous display devices include organic electroluminescent (EL) display devices and quantum-dot display devices. In particular, the quantum-dot display devices are attracting attention as next-generation displays because of their wide color gamut, excellent color purity, and low production costs.

A full-color quantum-dot display device includes quantum-dot light-emitting elements each provided for one of subpixels. A quantum-dot light-emitting element has a light-emitting layer containing quantum dots. The light-emitting layer is individually divided for each of the quantum-dot light-emitting elements. As a technique for forming such a plurality of light-emitting layers, for example, lift-off is employed. The lift-off is suitable for forming the light-emitting layers because the pattern accuracy is relatively high and steps such as etching can be omitted.

An example of quantum-dot display devices is disclosed in, for example, Patent Document 1.

### CITATION LIST

### Patent Literature

[Patent Document 1] International Publication No. WO/2023/286148

### SUMMARY

### Technical Problems

In manufacturing a quantum-dot display device, when the lift-off is used to form a light-emitting layer, first, a photoresist is formed on a surface, of a substrate, on which the light-emitting layer is to be formed. The photoresist has an opening at a predetermined position. Next, on the surface, of the substrate, on which the photoresist is formed, a light-emitting material containing quantum dots is applied and deposited. After that, the photoresist is removed, using a resist detaching solution. Hence, the light-emitting layer is formed only in a portion corresponding to the opening of the photoresist on the substrate.

In the process of forming the light-emitting layer, the applied light-emitting material is likely to accumulate on a portion along a circumference of the opening in the photoresist. Thus, an outer peripheral portion of the light-emitting material is likely to form a relatively thick accumulation. This accumulation is in contact with an inner surface inside the opening of the photoresist. As the photoresist is removed, the accumulation is liable for causing delamination of the light-emitting layer. When the light-emitting layer is delaminated, the delaminated portion becomes a non-light-emitting region. The non-light-emitting region deteriorates a light-emission characteristic of the quantum-dot light-emitting element and causes degradation in display quality.

An object of the present disclosure is directed to a self-luminous display device and sets out to reduce delamination of a light-emitting layer individually provided for each of light-emitting elements.

### Solution to Problems

The present disclosure is directed to a display device. A display device according to the present disclosure includes a plurality of light-emitting elements provided to correspond to a plurality of subpixels included in a display region. Each of the plurality of light-emitting elements has a light-emitting layer individually separated. The display region is provided with a dividing layer having a plurality of openings corresponding to the subpixels. Each of the openings of the dividing layer is provided with an inner peripheral surface formed to have either an upright surface standing upright in a thickness direction of the dividing layer, or a reverse-tapered angled surface so that the opening widens downwards of the dividing layer. Then, the light-emitting layer is provided inside the opening of the dividing layer.

The present disclosure is also directed to method for manufacturing the display device. A method for manufacturing a display device according to the present disclosure is a method for manufacturing a display device in which a plurality of light-emitting elements, each of which has a light-emitting layer individually separated, is provided to correspond to a plurality of subpixels included in a display region. The method for manufacturing the display device includes: a dividing layer forming step of forming, on a substrate, a dividing layer having a plurality of openings corresponding to the subpixels, each of the openings being provided with an inner peripheral surface formed to have either an upright surface standing upright in a thickness direction of the dividing layer, or a reverse-tapered angled surface so that the opening widens downwards of the dividing layer; and a light-emitting layer forming step of forming, on a substrate provided with the dividing layer, a photoresist having an opening at a predetermined position, depositing a light-emitting functional film on a portion exposed from the photoresist on the substrate and on the photoresist, and removing the photoresist together with the light-emitting functional film on the photoresist using a resist detaching solution, in order to form the light-emitting layer inside the opening of the dividing layer.

### Advantageous Effect of Disclosure

A technique of the present disclosure is directed to a self-luminous display device and reduces the risk of delamination of a light-emitting layer individually provided to each of the light-emitting elements.

### BRIEF DESCRIPTION OF DRAWINGS

FIG. 1 is a plan view illustrating an example of a quantum-dot display device according to a first embodiment.

FIG. 2 is a cross-sectional view of the quantum-dot display device, taken along line II-II in FIG. 1.

FIG. 3 is a plan view illustrating an example of pixels and various wires included in a display region according to the first embodiment.

FIG. 4 is a plan view illustrating an example of one subpixel and a configuration around the one subpixel observed through an EL layer and a layer above the EL layer.

FIG. 5 is a cross-sectional view of the display region, taken along line V-V in FIG. 3.

FIG. 6 is a cross-sectional view illustrating an example of a main portion included in the quantum-dot display device and surrounded with line VI in FIG. 5.

FIG. 7 illustrates cross-sectional views partially showing steps of manufacturing the quantum-dot display device according to the first embodiment.

FIG. 8 illustrates cross-sectional views partially showing steps of manufacturing the quantum-dot display device according to the first embodiment.

FIG. 9 illustrates cross-sectional views partially showing steps of manufacturing the quantum-dot display device according to the first embodiment.

FIG. 10 illustrates cross-sectional views partially showing steps of manufacturing the quantum-dot display device according to the first embodiment.

FIG. 11 illustrates cross-sectional views partially showing steps of manufacturing the quantum-dot display device according to the first embodiment.

FIG. 12 illustrates cross-sectional views partially showing steps of manufacturing the quantum-dot display device according to the first embodiment.

FIG. 13 illustrates cross-sectional views partially showing steps of manufacturing the quantum-dot display device according to the first embodiment.

FIG. 14 illustrates cross-sectional views partially showing steps of manufacturing the quantum-dot display device according to the first embodiment.

FIG. 15 illustrates cross-sectional views partially showing steps of manufacturing the quantum-dot display device according to the first embodiment.

FIG. 16 illustrates cross-sectional views partially showing steps of manufacturing the quantum-dot display device according to the first embodiment.

FIG. 17 illustrates cross-sectional views partially showing steps of manufacturing the quantum-dot display device according to the first embodiment.

FIG. 18 is a cross-sectional view illustrating an example of a main portion of the quantum-dot display device according to a second embodiment.

FIG. 19 is a cross-sectional view illustrating an example of a main portion of a light-emitting-element layer, taken along line XIX-XIX in FIG. 18.

FIG. 20 illustrates cross-sectional views partially showing steps of manufacturing the quantum-dot display device according to the second embodiment.

FIG. 21 illustrates cross-sectional views partially showing steps of manufacturing the quantum-dot display device according to the second embodiment.

FIG. 22 is a cross-sectional view illustrating a main portion of the quantum-dot display device according to a third embodiment.

FIG. 23 illustrates cross-sectional views partially showing steps of manufacturing the quantum-dot display device according to the third embodiment.

FIG. 24 illustrates cross-sectional views partially showing steps of manufacturing the quantum-dot display device according to the third embodiment.

FIG. 25 is a cross-sectional view illustrating an example of a main portion of the quantum-dot display device according to another embodiment.

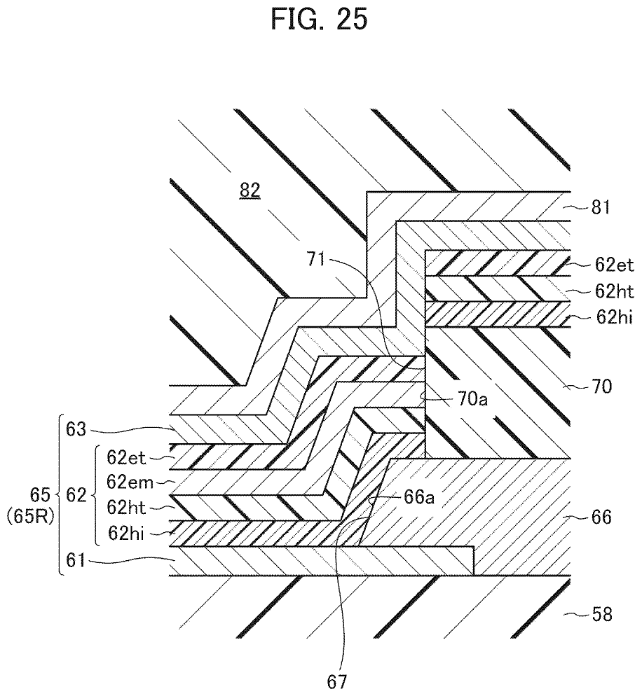

FIG. 26 is a cross-sectional view illustrating an example of another aspect of the main portion of the quantum-dot display device according to the first embodiment.

### DESCRIPTION OF EMBODIMENTS

Exemplary embodiments will be described in detail below with reference to the drawings. In the embodiments below, a quantum-dot display device will be described as an example of a display device according to the present disclosure. Note that the drawings conceptually illustrate techniques of the present disclosure. Hence, the drawings may either exaggerate or simplify the dimensions, ratios or numbers to facilitate understanding of the techniques of the present disclosure.

In the embodiments below, the term “first direction” means a lateral direction of the screen when the display device is under predetermined conditions of use. The term “second direction”, which is a direction perpendicular to the first direction, means a vertical direction of the screen when the display device is under predetermined conditions of use. A row of the constituent features such as subpixels means a lateral arrangement of a plurality of constituent features lined up in the first direction. A column of the constituent features such as subpixels means a vertical arrangement of a plurality of constituent features lined up in the second direction.

The embodiments below include a statement describing that, above a constituent feature such as a film, layer, or element, another constituent feature such as another film, layer or element is provided or formed. The statement means not only a case where the other constituent feature is found immediately above the constituent feature, but also a case where still another constituent feature such as still another film, layer, or element is provided between the constituent feature and the other constituent feature.

The embodiments below include a statement describing that a constituent feature is connected to another constituent feature. Such a statement means that the constituent features are electrically connected together unless otherwise specified. The statement means not only a case of direct connection but also a case of indirect connection through still another constituent feature unless otherwise departing from the scope of the present disclosure. Furthermore, the statement also includes a case where a constituent feature is integrated with another constituent feature, that is, a portion of a constituent feature constitutes another constituent feature.

The embodiments below include a statement describing that a constituent feature is included in the same layer as a layer of another constituent feature. Such a statement means that both of the constituent features are formed in the same process. A statement describes that a constituent feature is provided below another constituent feature. Such a statement means that the constituent feature is deposited either in a process preceding the process of the other constituent feature or formed of a film deposited in the preceding process. A statement describes that a constituent feature is provided above another constituent feature. Such a statement means that the constituent feature is deposited either in a process succeeding the process of the other constituent feature, or formed of a film deposited in the succeeding process.

The embodiments below include a statement describing that a constituent feature is the same as, or identical to, another constituent feature. Such a statement means not only a case where the constituent feature is completely the same as, or completely identical to, the other constituent feature, but also a case where the constituent feature is substantially the same as, or substantially identical to, the other constituent feature within production variation and tolerance.

The embodiments describe such terms as “first”, “second”, and “third”. These terms are used to distinguish between the phrases to which these terms are assigned and shall not limit the number and the order of the phrases.

### First Embodiment

A quantum-dot display device 1 of this embodiment is used for displays of mobile devices including multi-function phones such as smart phones and tablet terminals. The quantum-dot display device 1 may also be used for displays of other various devices such as personal computers (PCs) and TV devices.

### Schematic Configuration of Quantum-Dot Display Device

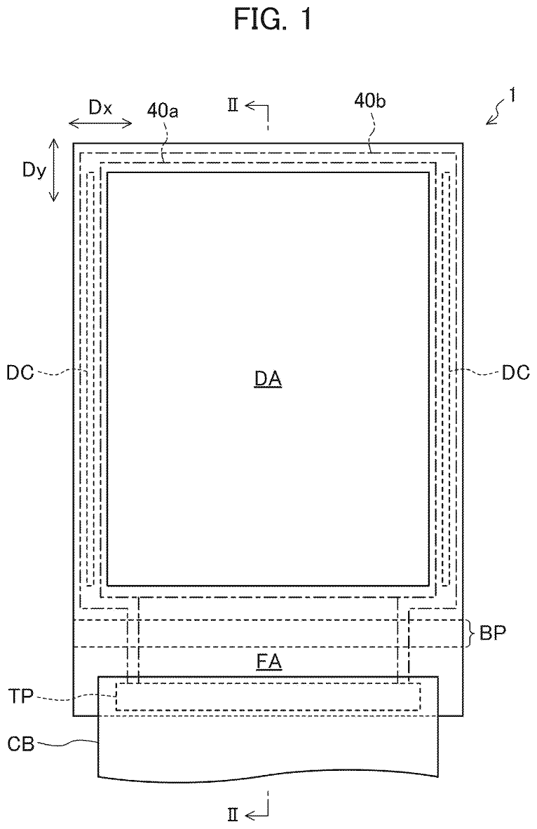

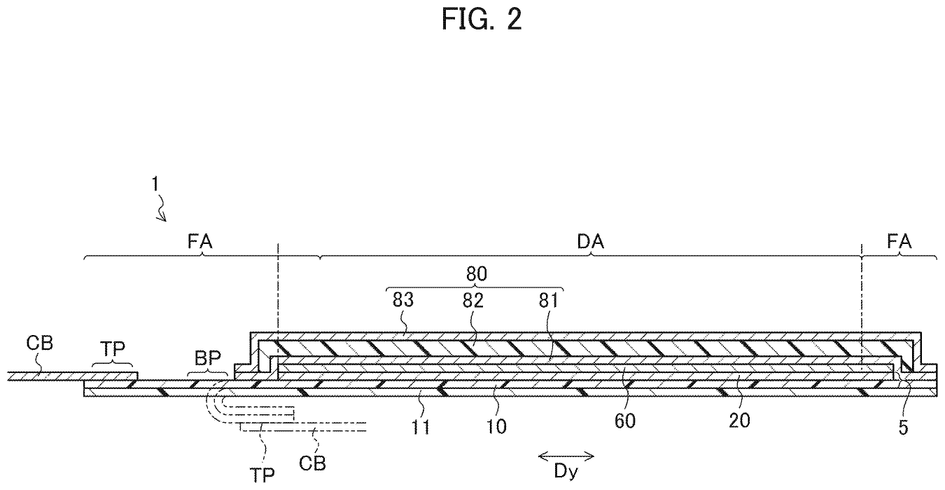

The quantum-dot display device 1 is a display device using a quantum-dot light-emitting element 65 also referred to as a quantum-dot light-emitting diode (QLED). The quantum-dot display device 1 is an active-matrix display device that displays an image in full color. As illustrated in FIGS. 1 and 2, the quantum-dot display device 1 has: a display region DA; and a picture-frame region FA.

The display region DA is a region to display an image and serves as a screen. The display region DA is shaped into, for example, a rectangle. The display region DA may be shaped into a substantial rectangle such as a rectangle having at least one of the sides as an arc-like side, a rectangle having at least one of the corners as a rounded corner, or a rectangle having at least one of the sides as a notched side. The display region DA may also be shaped into any given shape.

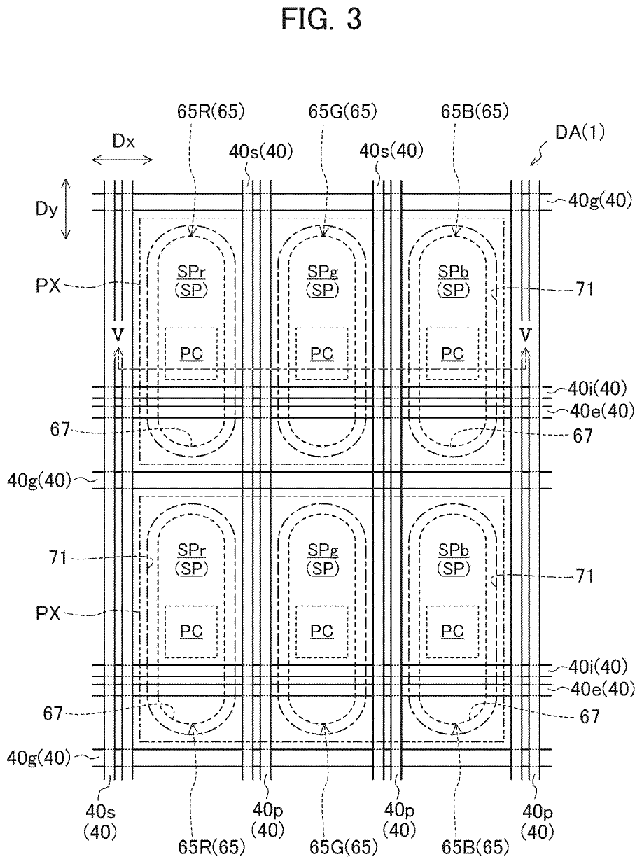

As illustrated in FIG. 3, the display region DA includes a plurality of pixels PX. The plurality of pixels PX is arranged in a matrix. Each of the pixels PX includes three subpixels SP. The three subpixels SP include a red subpixel Spr that emits a red light, a green subpixel Spg that emits a green light, and a blue subpixel Spb that emits a blue light. The red subpixel SPr, the green subpixel SPg, and the blue subpixel SPb are arranged, for example, in a striped pattern.

Each of the subpixels SPr, SPg, and SPb includes the quantum-dot light-emitting element 65. As can be seen, the quantum-dot display device 1 includes a plurality of the quantum-dot light-emitting elements 65 corresponding to the plurality of subpixels SP forming the display region DA. Each of the subpixels SP is provided with a pixel circuit PC. Each pixel circuit PC controls light to be emitted from the corresponding subpixel SP (the corresponding quantum-dot light-emitting element 65).

The picture-frame region FA is provided out of the screen and presents no image. As illustrated in FIGS. 1 and 2, the picture-frame region FA is shaped, for example, into a rectangular picture-frame shape and provided around the display region DA. The picture-frame region FA may be shaped into a frame other than a rectangle. The picture-frame region FA includes: a terminal unit TP; and a folding portion BP.

The terminal unit TP is a portion for connecting to an external circuit. The terminal unit TP is positioned closer to an outer edge included in one side of the picture-frame region FA, and extends in the first direction Dx along the one side. Although not shown, the terminal unit TP has a plurality of terminals. The terminal unit TP has a wiring board CB such as a flexible printed circuit (FPC) connected thereto.

The folding portion BP is provided between the terminal unit TP and the display region DA and extends transversely in the first direction Dx across the entire picture-frame region FA. The picture-frame region FA is folded at the folding portion BP at an angle of, for example, 180° in a U-shape (see a dash-dot-dot-dash line in FIG. 2). Thus, the terminal unit TP is laid in back of the quantum-dot display device 1.

Furthermore, the picture-frame region FA is provided with a drive circuit DC. In the picture-frame region FA, the drive circuit DC is disposed to each of the sides (the left side and the right side in FIG. 1) adjacent to the side provided with the terminal unit TP. The drive circuit DC is monolithically formed as a portion of a TFT layer 20 to be described later. The drive circuit DC includes: a gate driver; and an emission driver.

The picture-frame region FA further includes: a first picture-frame line 40a; and a second picture-frame line 40b. Both the first picture-frame line 40a and the second picture-frame line 40b are main power supply lines. The first picture-frame line 40a and the second picture-frame line 40b are formed to surround the display region DA, and extend to the terminal unit TP. The first picture-frame line 40a is supplied with a high-level power supply voltage (ELVDD) through the wiring board CB. The second picture-frame line 40b is supplied with a low-level power supply voltage (ELVDD) through the wiring board CB.

### Multilayer Structure of Quantum-Dot Display Device

As illustrated in FIG. 2, the quantum-dot display device 1 includes: a substrate layer 10; the thin-film transistor layer (the TFT layer) 20; a light-emitting element layer 60; and a sealing film 80. The substrate layer 10 and the TFT layer 20 constitute a circuit substrate 5 referred to as a backplane.

### Substrate Layer

The substrate layer 10 is a base layer of the quantum-dot display device 1. The substrate layer 10 is an example of a substrate. The substrate layer 10 is flexible. The substrate layer 10 is formed of an organic resin material such as polyimide resin, polyamide resin, or epoxy resin. The substrate layer 10 has a back face to which a protective film 11 is attached. The protective film 11 is transparent to light.

### TFT Layer

The TFT layer 20 is provided on the substrate layer 10. The TFT layer 20 includes: various wires 40; the plurality of pixel circuits PC; and a planarization film 58. The substrate layer 10 has a front face provided substantially entirely with a not-shown base coat film. The various wires 40, the pixel circuits PC, and the planarization film 58 are provided on the base coat film.

As illustrated in FIG. 3, the various wires 40 include: a plurality of gate lines 40g; a plurality of light-emission control lines 40e; a plurality of initialization lines 40i; a plurality of power supply lines 40p; and a plurality of source lines 40s. The gate lines 40g, the light-emission control lines 40e, the initialization lines 40i, the power supply lines 40p, and the source lines 40s are provided to the display region DA.

Each of the plurality of gate lines 40g is a wire to transmit a gate signal to the pixel circuits PC. The plurality of gate lines 40g is spaced apart from one another in the second direction Dy and extends in parallel with one another in the first direction Dx. The gate lines 40g are provided for the respective rows of the subpixels SP. Each of the gate lines 40g is led to the picture-frame region FA and connected to the gate driver of the drive circuit DC.

Each of the plurality of light-emission control lines 40e is a wire to transmit an emission signal to the pixel circuits PC. The plurality of light-emission control lines 40e is spaced apart from one another in the second direction Dy and extends in parallel with one another in the first direction Dx. The light-emission control lines 40e are provided for the respective rows of the subpixels SP. Each of the light-emission control lines 40e is led to the picture-frame region FA and connected to the emission driver of the drive circuit DC.

The initialization lines 40i are wires to apply an initialization voltage to the pixel circuits PC. The plurality of initialization lines 40i is spaced apart from one another in the second direction Dy and extends in parallel with one another in the first direction Dx. The initialization lines 40i are provided for the respective rows of the subpixels SP. Each of the initialization lines 40i is led to the picture-frame region FA and connected to either the drive circuits DC or the second picture-frame line 40b.

Each of the plurality of power supply lines 40p is a wire to apply a predetermined high-level power supply voltage (ELVDD) to the pixel circuits PC. The plurality of power supply lines 40p is spaced apart from one another in the first direction Dx and extends in parallel with one another in the second direction Dy. The power supply lines 40p are provided for the respective columns of the subpixels SP. Each of the power supply lines 40p is led to the picture-frame region FA and connected to the first picture-frame line 40a.

Each of the plurality of source lines 40s is a wire to transmit a source signal to the pixel circuits PC. The plurality of source lines 40s is spaced apart from one another in the first direction Dx and extends in parallel with one another in the second direction Dy. The source lines 40s are provided for the respective columns of the subpixels SP. Each of the source lines 40s is led to the terminal unit TP and connected to a display control circuit (a source driver) through the wiring board CB.

The gate lines 40g and the light-emission control lines 40e are formed of the same material and in the same layer provided on the base coat film. Above the base coat film, such not-shown films as a gate insulating film, a first interlayer insulating film, and a second interlayer insulating film are stacked on top of another in the stated order to cover the gate lines 40g and the light-emission control lines 40e. The initialization lines 40i are provided on the first interlayer insulating film. The power supply lines 40p and the source lines 40s are formed of the same material and in the same layer provided on the second interlayer insulating film.

Each of the pixel circuits PC is provided to a corresponding one of the plurality of subpixels SP. The gate lines 40g, the light-emission control lines 40e, the initialization lines 40i, and the power supply lines 40p are connected to the pixel circuits PC. Each of the pixel circuits PC includes: a plurality of TFTs 50; and at least one capacitor 55. Each pixel circuit PC includes, for example, seven TFTs 50.

A TFT 50 is, for example, a top-gate TFT. Although not shown, the TFT 50 has: a gate electrode; a first terminal electrode; and a second terminal electrode. The gate electrode is formed of the same material as, and in the same layer as, for example, the gate line 40g. The first terminal electrode and the second terminal electrode are formed of the same material as, and in the same layer as, for example, the source line 40s.

Although not shown, the capacitor 55 has: a first capacitive electrode; and a second capacitive electrode. The first capacitive electrode and the second capacitive electrode overlap with each other through an insulating film included in the TFT layer 20. The first capacitive electrode is formed of the same material as, and in the same layer as, for example, the gate line 40g. The second capacitive electrode is formed of the same material as, and in the same layer as, for example, the initialization line 40i.

The pixel circuit PC operates in accordance with the gate signal, the emission signal, the initialization voltage, and the high-level power supply voltage (ELVDD) respectively supplied through the gate line 40g, the emission control line 40e, the initialization line 40i, and power supply line 40p. In each of frames, the pixel circuit PC resets charges accumulated in the first electrode 61. After that, the pixel circuit PC supplies the quantum-dot light-emitting element 65 with a drive current corresponding to the source signal.

The various wires and electrodes described above are made of such metal materials as, for example, aluminum (Al), tungsten (W), molybdenum (Mo), tantalum (Ta), chromium (Cr), titanium (Ti), and copper (Cu). These various wires and electrodes may be monolayer films or multilayer films.

Each of the base coat film, the gate insulating film, the first interlayer insulating film, and the second interlayer insulating film is an inorganic insulating film formed of such an inorganic insulating material as, for example, silicon oxide, silicon nitride, or silicon oxynitride. Each of these various inorganic insulating films may be formed of a monolayer film or a multilayer film.

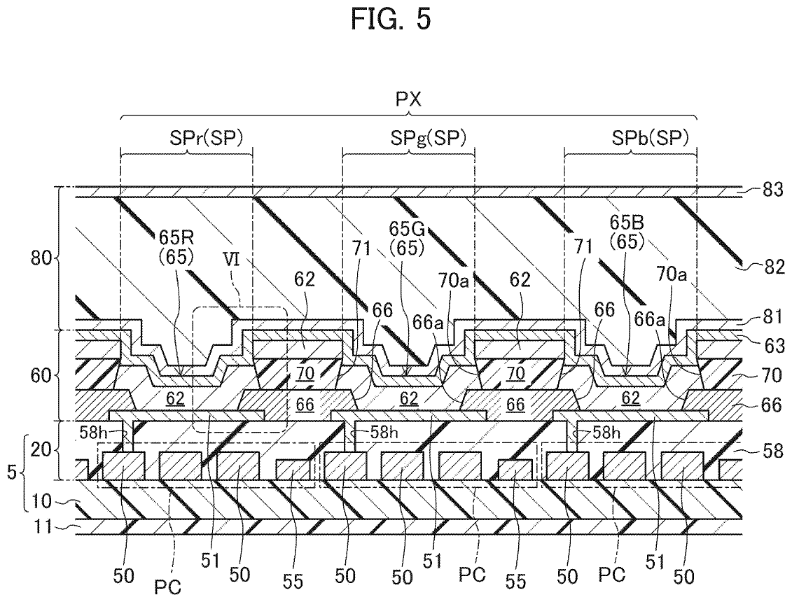

As illustrated in FIG. 5, the planarization film 58 is provided to cover the plurality of TFTs 50 and the capacitors 55. The planarization film 58 extends over the entire display region DA. The planarization film 58 has a contact hole 58h formed for each of the subpixels SP. The contact hole 58h reaches either the first terminal electrode or the second terminal electrode of a predetermined TFT 50. Alternately, the contact hole 58h reaches a wire to be connected to either the first terminal electrode or the second terminal electrode.

The planarization film 58 is made of, for example, such an organic resin material as polyimide resin or acrylic resin. Alternatively, the planarization film 58 is made of a polysiloxane-based spin-on-glass (SOG) material. The planarization film 58 may be a monolayer film or a multilayer film. The TFT layer 20 has a surface planarized with the planarization film 58.

### Light-Emitting Element Layer

The light-emitting-element layer 60 is provided on the TFT layer 20. The light-emitting-element layer 60 includes: the plurality of quantum-dot light-emitting elements 65; an edge cover 66; and a dividing layer 70. The quantum-dot light-emitting elements 65 are an example of light-emitting elements. The quantum-dot light-emitting elements 65 are top-emission light-emitting elements. Light emitted from the quantum-dot light-emitting elements 65 is released toward the sealing film 80.

The plurality of quantum-dot light-emitting elements 65 is provided to the display region DA. Specifically, each of the quantum-dot light-emitting elements 65 is provided to a corresponding one of the plurality of subpixels SP. Each of the quantum-dot light-emitting elements 65 is included in a subpixel SP. Light to be emitted from each quantum-dot light-emitting element 65 is controlled by an operation of the corresponding pixel circuit PC.

The quantum-dot light-emitting elements 65 includes a plurality of kinds of quantum-dot light-emitting elements 65 each of which emits light in a different color. The plurality of kinds of quantum-dot light-emitting elements 65 include: a red light-emitting element 65R; a green light-emitting element 65G; and a blue light-emitting element 65B. Each of the plurality of quantum-dot light-emitting elements 65 includes: the first electrode 61; an electroluminescent layer (an EL layer) 62; and a second electrode 63.

Each of the plurality of quantum-dot light-emitting elements 65 has a light-emitting layer 62em individually separated as a portion of the EL layer 62. The red light-emitting element 65R has a red light-emitting layer 62emr serving as the light-emitting layer 62em to emit a red light. The green light-emitting element 65G has a green light-emitting layer 62emg serving as the light-emitting layer 62em to emit a green light. The blue light-emitting element 65B has a blue light-emitting layer 62emb serving as the light-emitting layer 62em to emit a blue light.

The first electrode 61 is individually separated and provided on the planarization film 58. A plurality of the first electrodes 61 is arranged in a matrix in association with one of the plurality of the subpixels SP. The first electrode 61 is connected to a predetermined TFT 50 through a contact hole 58h of the planarization film 58. The first electrode 61 functions as a positive electrode and injects holes into the EL layer 62. The first electrode 61 is preferably formed of a conductive material having a large work function.

Examples of the material for the first electrode 61 include such metals as silver (Ag), aluminum (Al), nickel (Ni), titanium (Ti), indium (In), and tin (Sn). The material for the first electrode 61 may be a metal compound or an alloy. The material for the first electrode 61 may be such a conductive oxide as indium tin oxide (ITO) or indium zinc oxide (IZO). The first electrode 61 may be a monolayer film or a multilayer film.

As a more specific example, the first electrode 61 includes: an indium tin oxide layer (an ITO layer); a silver alloy layer (a Ag alloy layer); and an indium tin oxide layer (an ITO layer), all of which are stacked on top of another in the stated order. The first electrode 61 may have a silver layer (a Ag layer) instead of the silver alloy layer (the Ag alloy layer). Furthermore, the first electrode 61 may include: an aluminum layer (an Al layer); and an indium zinc oxide layer (an IZO layer), both of which are stacked on top of another in the stated order.

The edge cover 66 is provided on the planarization film 58 in the display region DA. The edge cover 66 is formed in a grid pattern to partition the plurality of first electrodes 61 from one another. The edge cover 66 is positioned above the first electrodes 61 and provided to extend between the first electrodes 61 adjacent to each other and to cover an outer edge (a peripheral end portion) of each of the first electrodes 61.

The edge cover 66 has a plurality of openings 67 corresponding to the subpixels SP. Each of the openings 67 partially exposes the first electrode 61. Each of the openings 67 of the edge cover 66 is provided with an inner peripheral surface 66a formed to have a tapered (forward-tapered) angled surface so that the opening 67 narrows downwards of the edge cover 66; that is, in this example, toward the planarization film 58.

The edge cover 66 may be formed of, for example, an organic insulating material similar to that of the planarization film 58. Examples of the organic insulating material include: organic resin materials such as polyimide resin and acrylic resin; and a polysiloxane-based spin-on-glass (SOG) material. The edge cover 66 may be formed of an inorganic insulating material. As a more specific example, the edge cover 66 is formed of silicon nitride (SiNₓ).

The dividing layer 70 is provided on the edge cover 66 in the display region DA. The dividing layer 70 is formed in a grid pattern in conformity with the edge cover 66. A dimension W1 of the dividing layer 70 in a width direction is smaller than a dimension W2 of the edge cover 66 in the width direction. Here, the “width direction” means a direction perpendicular to a direction in which a portion between the adjacent first electrodes 61 linearly extends.

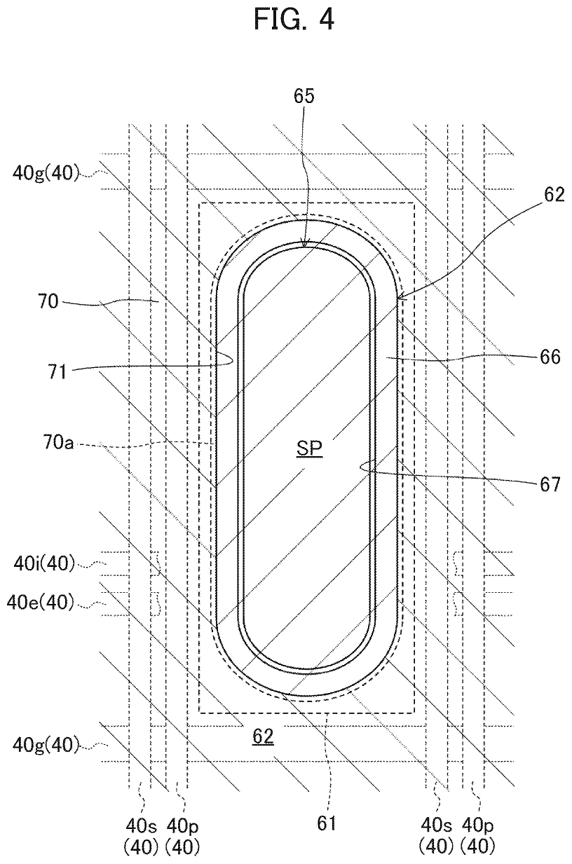

As illustrated in FIG. 4, the dividing layer 70 has the plurality of openings 71 corresponding to the subpixels SP. Each of the openings 71 is formed to contain one of the openings 67 of the edge cover 66 in a plan view. That is, in a plan view, the opening 67 of the edge cover 66 is completely positioned inside the opening 71 of the dividing layer 70. Each of the openings 71 of the dividing layer 70 exposes a peripheral edge portion of the opening 67 of the edge cover 66 and a region corresponding to an interior of the opening 67 of the edge cover 66.

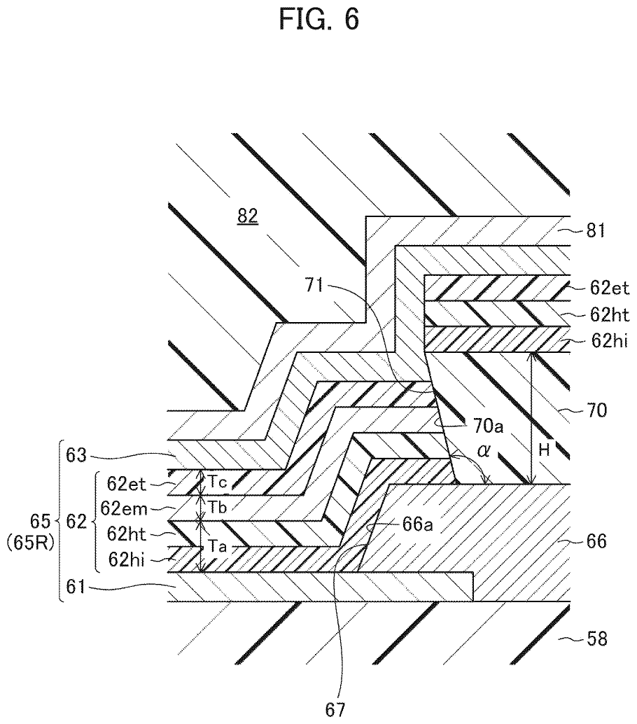

The quantum-dot light-emitting element 65 is provided inside each opening 71 of the dividing layer 70. Each of the openings 71 of the dividing layer 70 is provided with an inner peripheral surface 70a formed to have a reverse-tapered angled surface so that the opening 71 widens downwards of the dividing layer 70; that is, in this example, toward the edge cover 66. As illustrated in FIG. 6, the inner peripheral surface 70a of each of the openings 71 of the dividing layer 70 is angled so that an angle α, formed inwards the dividing layer 70 with respect to a direction perpendicular to a thickness direction of the dividing layer 70, is within a predetermined angle range. Here, the predetermined angle range is, for example, greater than, or equal to, 90 degrees and smaller than, or equal to, 130 degrees.

As can be seen, the inner peripheral surface 70a of the dividing layer 70 has a reverse-tapered angled surface. Such an angled surface is advantageous in dividing the light-emitting layer 62em between inside the opening 71 of the dividing layer 70 and upwards the dividing layer 70 in a lift-off process for forming the light-emitting layer 62em. The dividing layer 70 may be formed of either an organic material or an inorganic material. Specific examples of the organic material used for the dividing layer 70 include acrylic resin and novolak resin.

The EL layer 62 (hatched with diagonally upward lines to the right in FIG. 4) is provided inside the opening 71 of the dividing layer 70. More specifically, the EL layer 62 is provided on an individual first electrode 61 inside the opening 67 of the edge cover 66. The EL layer 62 has an outer peripheral portion provided over the peripheral edge portion of the opening 67 of the edge cover 66. The EL layer 62 has a portion (i.e., a hole injection layer 62hi, a hole transport layer 62ht, and an electron transport layer 62et hatched with diagonally upward lines to the left in FIG. 4 to be described later) also provided above the dividing layer 70.

If a thickness of the EL layer 62 is excessively small, electricity leaks. Furthermore, if a thickness Ta of the EL layer 62 is excessively large, a drive voltage rises. The thickness of the EL layer 62 is set to a thickness for avoiding the electrical leakage and reducing the rise of the drive voltage. As illustrated in FIG. 6, the EL layer 62 in this example includes: the hole injection layer 62hi; the hole transport layer 62ht; the light-emitting layer 62em; and the electron transport layer 62et. The hole injection layer 62hi, the hole transport layer 62ht, the light-emitting layer 62em, and the electron transport layer 62et are stacked on top of another in the stated order above the first electrode 61.

Each of the hole injection layer 62hi and the hole transport layer 62ht is a lower functional layer to move the holes from the first electrode 61 to the light-emitting layer 62em. The holes are an example of first carriers. The electron transport layer 62et is an upper functional layer to move the electrons from the second electrode 63 to the light-emitting layer 62em. The electrons are an example of second carriers.

The hole injection layer 62hi has a function of improving efficiency in injecting the holes from the first electrode 61 to the EL layer 62. The hole injection layer 62hi is formed of a known compound suitable for the function of injecting the holes. The hole injection layer 62hi may be formed of either an organic material or an inorganic material. The organic material for the hole injection layer 62hi may be either a low-molecular material or a polymeric material.

Specific examples of the polymeric material to be used for the hole injection layer 62hi include a composite (PEDOT: PSS) containing poly(3,4-ethylenedioxythiophene) (PEDOT) and polystyrene sulphonate (PSS). Specific examples of the inorganic material to be used for the hole injection layer 62hi include: nickel oxide (NiO); nickel oxide nanoparticles (NiO-NPs); and copper thiocyanate (CuSCN). Among the inorganic materials, the nickel oxide nanoparticles (NiO-NPs) are preferable as a material for the hole injection layer hi because the nickel oxide nanoparticles (NiO-NPs) are highly resistant to an alkali developing solution to be used in the lift-off process of this example for forming the light-emitting layer 62em. The hole injection layer 62hi of this example contains the nickel oxide nanoparticles (NiO-NPs).

The hole transport layer 62ht has a function of efficiently transporting the holes to the light-emitting layer 62em. The hole transport layer 62ht is formed of a known compound suitable for the function of transporting the holes. The hole transport layer 62ht may be formed of either an organic material or an inorganic material. The organic material for the hole transport layer 62ht may be either a low-molecular material or a polymeric material.

Specific examples of the polymeric material to be used for the hole transport layer 62ht include: poly[(9,9-dioctylfluorenyl-2,7-diyl)-co-(4,4′-(N-(4-sec-butylphenyl))diphenylamine)](TFB); poly[N,N′-bis(4-butylphenyl)-N,N′-bis(phenyl)-benzidine](p-TPD); and poly(N-vinylcarbazole) (PVK). These polymeric materials (TFB, p-TPD, and PVK) are highly resistant to alkali developing solution and thus preferable.

If the thicknesses of the lower functional layers; that is, in this example, a total thickness of the hole injection layer 62hi and the hole transport layer 62ht, is set to Ta [nm], the thickness Ta of the lower functional layers is set to satisfy, for example, 10≤Ta≤200. Preferably, the thickness Ta of the lower functional layers satisfies 40≤Ta≤100 in view of avoiding electrical leakage and a rise of the drive voltage, and simultaneously, efficiently injecting and transporting the holes. More preferably, the thickness Ta of the lower functional layers satisfies 50≤Ta≤80.

When a voltage is applied to the EL layer 62 through the first electrode 61 and the second electrode 63, the light-emitting layer 62em recombines the holes injected from the first electrode 61 and the electrons injected from the second electrode 63 to be in the excited state. When the light-emitting layer 62em returns to the ground state, energy is released and the light-emitting layer 62em emits light. The light-emitting layer 62em contains quantum dots. A color of the light emitted from the light-emitting layer 62em varies depending on a particle size and a material for the quantum dots.

The particle size of the quantum dots is selected for each of the colors that the subpixels SP have, in accordance with a color of light that the light-emitting layer 62em emits. The quantum dots have a particle size of approximately several nanometers to a dozen nanometers. Typically, the larger the particle size of the quantum dots is, the longer the wavelength of light emitted from the light-emitting layer 62em is. Hence, the particle size of the quantum dots increases in the order of the blue light-emitting layer 62emb, the green light-emitting layer 62emg, and the red light-emitting layer 62emr.

The quantum dots are formed of a semiconductor material. The semiconductor material includes at least one selected from the group consisting of, for example, a group II-VI compound, a group III-V compound, a group IV compound, a compound having a chalcopyrite structure, and a compound having a perovskite structure. Specific examples of the II-VI group compound include cadmium selenide (CdSe) and zinc selenide (ZnSe). Specific examples of the III-V group compound include indium phosphide (InP).

Each of the quantum dots may have what is referred to as a core-shell structure including: a core for emitting light; and a shell coating a surface of the core. Here, the particle size of the quantum dot is determined depending on a size of the core. The core is formed of the semiconductor material described above. The shell is also formed of a semiconductor material as the core is. The semiconductor material to be used for the shell is selected according to the semiconductor material to be used for the core. For example, the semiconductor material for the shell is larger in bandgap than the semiconductor material for the core.

If the light-emitting layer 62em has a thickness of Tb, the thickness Tb of the light-emitting layer 62em is set to satisfy, for example, 10≤Tb ≤100. Preferably, the thickness Tb of the light-emitting layer 62em satisfies 15≤Tb≤70 in view of avoiding electrical leakage and a rise of the drive voltage, and, simultaneously, efficiently injecting carriers (the holes and the electrons) into the light-emitting layer 62em itself. More preferably, the thickness Tb of the light-emitting layer 62em satisfies 20≤Tb ≤50.

The electron transport layer 62et has a function of efficiently transporting the electrons to the light-emitting layer 62em. The electron transport layer 62et is formed of a known compound suitable for the function of transporting the electrons. The electron transport layer 62et may be formed of either an organic material or an inorganic material. As the inorganic material for the electron transport layer 62et, for example, metal oxide nanoparticles are used. Specific examples of the metal oxide nanoparticles include zinc oxide nanoparticle (ZnO-NPs) and zinc magnesium oxide nanoparticles (MgZnO-NPs).

If the thickness of the upper functional layer; that is, in this example, a thickness of the electron transport layer 62et, is set to Tc [nm], the thickness Tc of the electron transport layer 62et is set to satisfy, for example, 10≤Tc ≤300. Preferably, the thickness Tc of the electron transport layer 62et satisfies 30≤Tc ≤200 in view of avoiding electrical leakage and a rise of the drive voltage, and simultaneously, efficiently injecting and transporting the electrons. More preferably, the thickness Tc of the electron transport layer 62et satisfies 50≤Tc≤150.

The light-emitting layer 62em is provided inside the opening 71 of the dividing layer 70, but not on the dividing layer 70. The hole injection layer 62hi, the hole transport layer 62ht, and the electron transport layer 62et are provided in each of the openings 71 of the dividing layer 70 and on the dividing layer 70. The inner peripheral surface 70a of each opening 71 of the dividing layer 70 forms a level difference. The level difference divides the hole injection layer 62hi, the hole transport layer 62ht, and the electron transport layer 62et inside the opening 71 of the dividing layer 70 from the hole injection layer 62hi, the hole transport layer 62ht and the electron transport layer 62et above the dividing layer 70.

A thickness of the dividing layer 70 is set so that the level difference of the inner peripheral surface 70a of the opening 71 divides the light-emitting layer 62em and leaves the second electrode 63 undivided. Specifically, if the total thickness of the hole injection layer 62hi and the hole transport layer 62ht in a center portion of the EL layer 62 is set to Ta [nm], a thickness of the light-emitting layer 62em is set to Tb [nm], and the thickness of the electron transport layer 62et is set to Tc [nm], a thickness H [nm] of the dividing layer 70 is set to satisfy a relational expression (Expression 1) below.

$$Ta + 3 Tb < H \leq 3 ( Ta + Tb + Tc ) + 200 . \qquad ( Expression 1 )$$

The second electrode 63 is provided over the entire display region DA to serve as a continuous common film across the plurality of subpixels SP. The second electrode 63 covers the dividing layer 70 and the EL layer 62 and overlaps with each of the first electrodes 61 through the EL layer 62. The second electrode 63 extends also to the picture-frame region FA and connects to the second picture-frame line 40b. The second electrode 63 functions as a negative electrode and injects the electrons into the EL layer 62. The second electrode 63 is preferably formed of a material having a small work function.

Examples of the material for the second electrode 63 include conductive oxides such as indium tin oxide (ITO) and indium zinc oxide (IZO). The material for the second electrode 63 may be a metal such as silver (Ag), aluminum (Al), lithium (Li), magnesium (Mg), calcium (Ca), or ytterbium (Yb).

The material for the second electrode 63 may be a metal compound or an alloy. Specific examples of the alloy to be used for the second electrode 63 include an alloy of magnesium silver (MgAg). As the material for the second electrode 63, metal nanowires such as silver nanowires (Ag-NWs) may be used. The second electrode 63 may be a monolayer film or a multilayer film.

### Sealing Film

The sealing film 80 is provided on the light-emitting-element layer 60. As illustrated in FIG. 5, the sealing film 80 covers to seal the plurality of quantum-dot light-emitting elements 65 and protects each of the quantum-dot light-emitting elements 65 (in particular, the EL layer 62) from such foreign objects as water and oxygen. The sealing film 80 is provided over the entire display region DA and extends to the picture-frame region FA. The sealing film 80 includes: a first inorganic film 81; an organic film 82; and a second inorganic film 83.

The first inorganic film 81, the organic film 82, and the second inorganic film 83 are provided above the light-emitting-element layer 60 in the stated order. The first inorganic film 81 and the second inorganic film 83 extend further toward an outer periphery of the picture-frame region FA than the organic film 82, and overlap with each other outside the picture-frame region FA. The organic film 82 is wrapped with the first inorganic film 81 and the second inorganic film 83.

Each of the first inorganic film 81 and the second inorganic film 83 is formed of such an inorganic insulating material such as, for example, silicon oxide, silicon nitride, or silicon oxynitride. The organic film 82 is formed of such an organic resin material as, for example, acrylic resin, epoxy resin, silicone resin, polyurea resin, parylene resin, polyimide resin, or polyamide resin.

### Method for Manufacturing Quantum-Dot Display Device

In order to manufacture the quantum-dot display device 1, first, a surface of a glass substrate 100 is coated with an organic resin material and baked. Thus, the substrate layer 10 is formed on the glass substrate 100.

Next, using such known deposition techniques as the plasma chemical vapor deposition (CVD), sputtering, vacuum deposition, such known coating techniques as spin coating and slit coating, and such known patterning techniques as photolithography and lift-off, the TFT layer 20, the light-emitting-element layer 60, and the sealing film 80 are formed in the stated order above the substrate layer 10.

Then, a laser beam is emitted from toward the glass substrate 100 to a back face of the substrate layer 10. Thus, the glass substrate 100 is removed from the substrate layer 10. Then, a polarizing plate and a cover panel are attached to a surface of the sealing film 80. Furthermore, the wiring board CB is connected to the terminal unit TP. Thus, the display control circuit is mounted on a panel serving as the quantum dot display device 1.

As described above, the quantum-dot display device 1 is successfully manufactured.

### Step of Forming Light-Emitting-Element Layer

A step of forming the light-emitting-element layer 60 includes: a first electrode forming step; an edge cover forming step; a dividing layer forming step; an EL layer forming step; and a second electrode forming step. The first electrode forming step, the edge cover forming step, the dividing layer forming step, the EL layer forming step, and the second electrode forming step are carried out in the stated order.

### First Electrode Forming Step

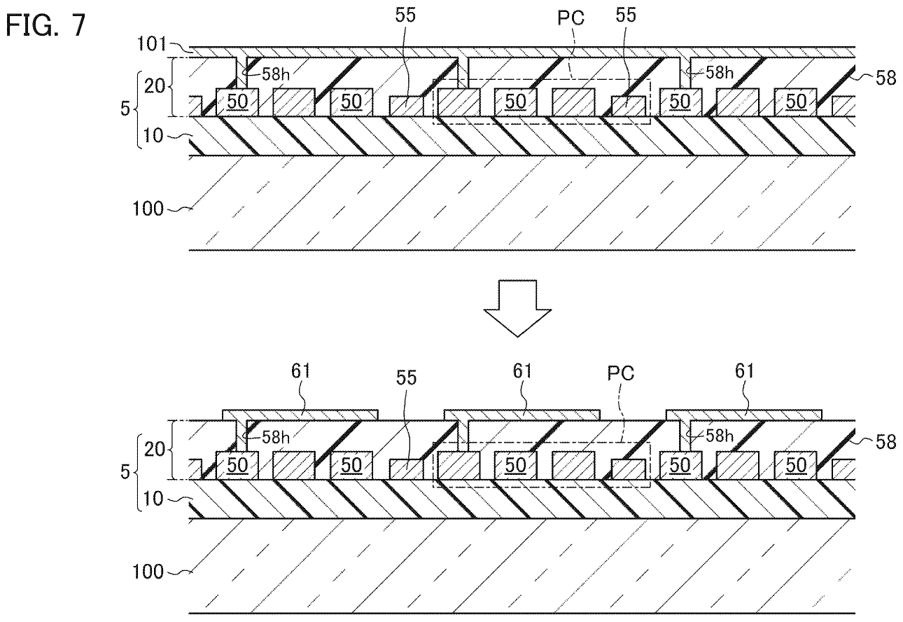

The first electrode forming step is a step of forming, on the substrate, the plurality of first electrodes 61 individually separated from one another. The first electrode forming step is carried out as follows. As illustrated in a view in the top of FIG. 7, first, on the substrate provided with the planarization film 58, for example, an indium tin oxide film (an ITO film), either a silver alloy film (a Ag alloy film) or a silver film (a Ag film), and an indium tin oxide film (an ITO film) are sequentially deposited by sputtering. Alternatively, an aluminum film (an Al film) and an indium zinc oxide film (an IZO film) are sequentially deposited. Thus, a metal film 101 is formed on the planarization film 58. Next, as illustrated in a view in the bottom of FIG. 7, the metal film 101 is patterned by photolithography to form the first electrodes 61.

### Edge Cover Forming Step

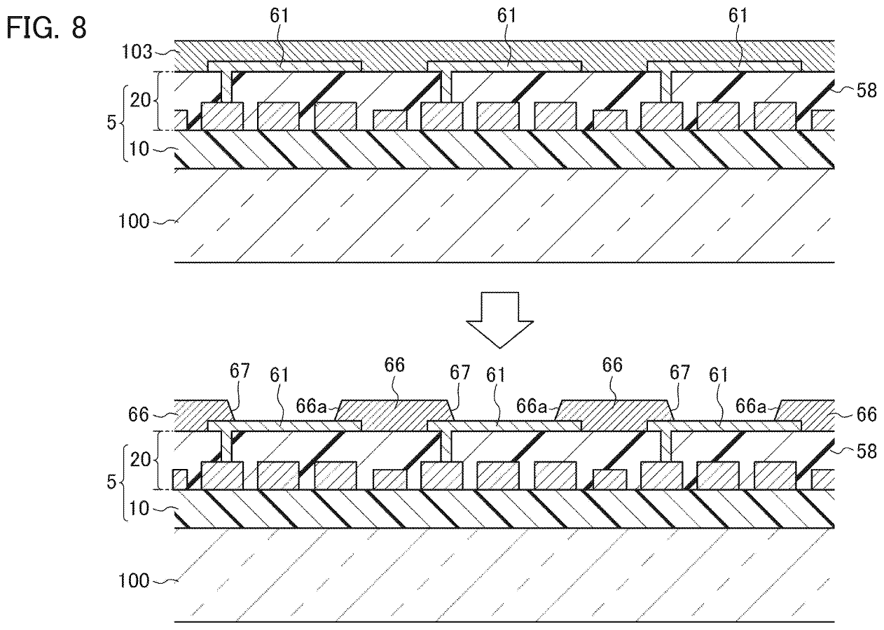

The edge cover forming step is a step of forming, on the substrate, the edge cover 66 that covers an outer edge of each of the first electrodes 61. The edge cover 66 has the plurality of openings 67 corresponding to the subpixels SP. The edge cover forming step is carried out as follows. As illustrated in a view in the top of FIG. 8, on the substrate provided with the first electrodes 61, for example, a silicon nitride film (a SiNₓ film) 103 is deposited by the plasma CVD. Next, as illustrated in a view in the bottom of FIG. 8, the silicon nitride film 103 is patterned by photolithography to form the edge cover 66.

### Dividing Layer Forming Step

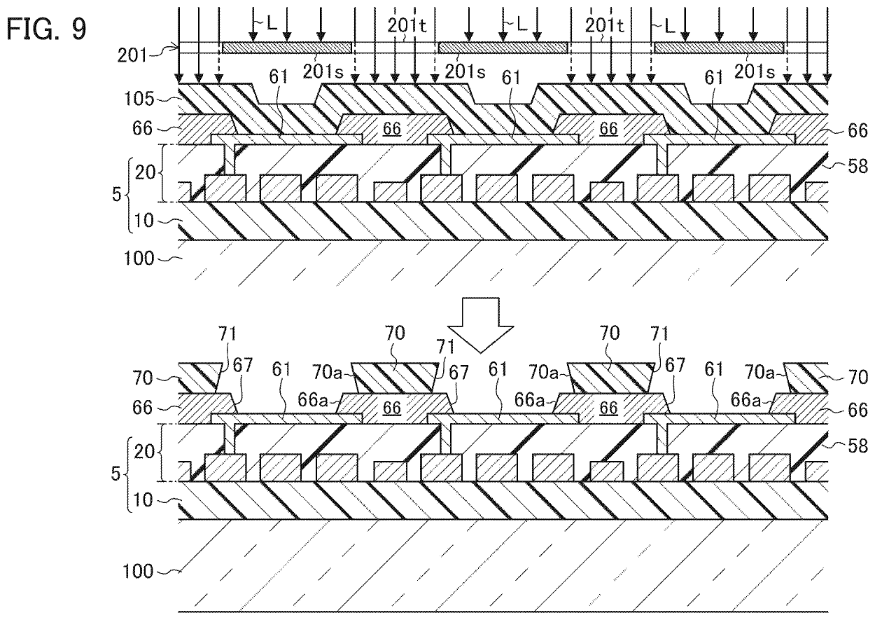

The dividing layer forming step is a step of forming, on the substrate, the dividing layer 70 that is shaped in conformity with the edge cover 66. The dividing layer 70 has the plurality of openings 71 corresponding to the subpixels SP. The dividing layer forming step is carried out as follows. First, the substrate provided with the edge cover 66 is coated with an acrylic photosensitive resin by a known coating technique. Hence, the photosensitive resin forms a coating film 105 (see a view in the top of FIG. 9). In this example, the photosensitive resin is a negative photosensitive resin. Next, the coating film 105 formed of the photosensitive resin is prebaked, exposed to light, developed, and postbaked. Hence, as illustrated in a view in the bottom of FIG. 9, the dividing layer 70 is formed on the edge cover 66.

In the exposure processing, as illustrated in the view in the top of FIG. 9, the coating film 105 formed of the photosensitive resin is irradiated with light L through a photomask 201 so that the photosensitive resin reacts to the light L. The photomask 201 to be used in the exposure processing of this example has: a light-blocking portion 201s that blocks light from an unnecessary portion in the coating film 105 formed of the photosensitive resin; and a light-transmitting portion 201t that transmits the light L to a portion in which the dividing layer 70 is formed. When the exposure processing is carried out using the photomask 201, an exposure dose (an exposure dose indicated by arrows in broken lines in FIG. 9) at the light-blocking portion 201s is slightly lower than an exposure dose at a center of the light-transmitting portion 201t. Hence, a phenomenon is observed; that is, a portion included in the coating film 105 and corresponding to the light-blocking portion 201s is less likely to cure to the bottom of the portion. Taking advantage of this phenomenon, in this example, the dividing layer 70 is formed so that the inner peripheral surface 70a of each of the openings 71 is formed to have a reverse-tapered angled surface.

### EL Layer Forming Step

The EL layer forming step is a step of forming the EL layer 62 on the plurality of first electrodes 61. The EL layer forming step includes: a lower functional layer forming step; a light-emitting layer forming step; and an upper functional layer forming step. The lower functional layer forming step, the light-emitting layer forming step, and the upper functional layer forming step are carried out in the stated order.

### Lower Functional Layer Forming Step

The lower functional layer forming step is a step of forming a functional layer included in the EL layer 62 and provided below the light-emitting layer 62em; that is, in this example, a step of forming the hole injection layer 62hi and the hole transport layer 62ht.

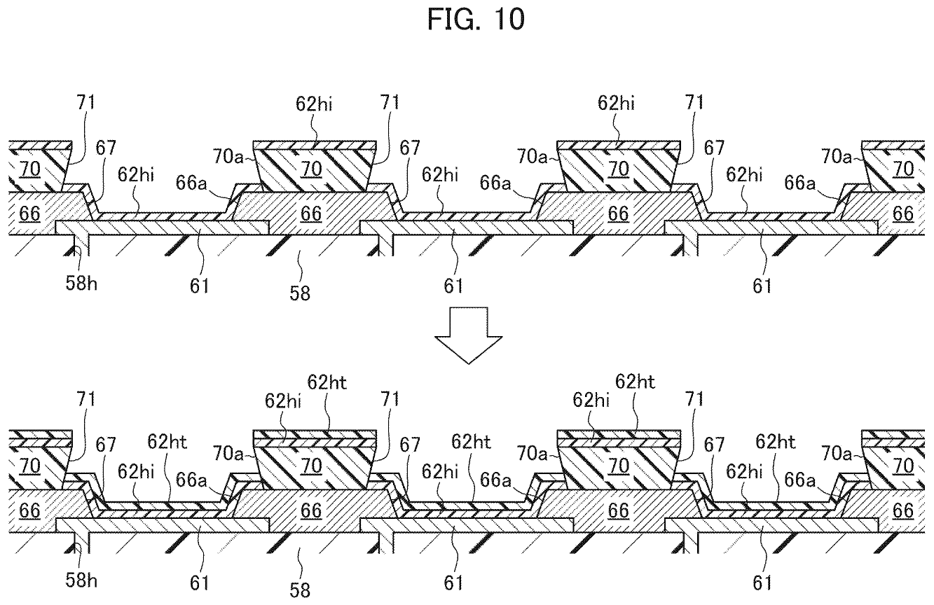

The lower functional layer forming step is carried out as follows. First, the substrate provided with the first electrodes 61 is coated with a solution by a known coating technique. The solution contains the above-described compound suitable for the function of injecting holes. Hence, the solution forms a coating film. Then, the coating film is baked so that the solvent is vaporized. Hence, as illustrated in a view in the top of FIG. 10, the hole injection layer 62hi is formed inside each of the openings 71 of the dividing layer 70 and on the dividing layer 70. Specifically, for example, the hole injection layer 62hi is formed of nickel oxide nanoparticles (NiO-NPs).

Next, the substrate provided with the hole injection layer 62hi is coated with a solution by, for example, a known coating technique. The solution contains the above-described compound suitable for the function of transporting holes. Hence, the solution forms a coating film. Then, the coating film is baked so that the solvent is vaporized. Hence, as illustrated in a view in the bottom of FIG. 10, the hole transport layer 62ht is formed inside each of the openings 71 of the dividing layer 70 and above the dividing layer 70. Specifically, for example, the hole transport layer 62ht is formed of the TFB, the p-TPD, or the PVK.

Both the hole injection layer 62hi and the hole transport layer 62ht formed in the above process are divided with the level difference of the inner peripheral surface 70a of the opening 71 of the dividing layer 70. That is, the hole injection layer 62hi and the hole transport layer 62ht both provided inside the opening 71 of the dividing layer 70 are divided from the hole injection layer 62hi and the hole transport layer 62ht provided above the dividing layer 70.

### Light-Emitting Layer Forming Step

The light-emitting layer forming step is a step of forming the light-emitting layer 62em on the hole transport layer 62ht using lift-off. At the light-emitting layer forming step, a lift-off process is carried out. The lift-off process includes: a step of forming a photoresist 109; a step of depositing a light-emitting functional film 113; and a step of removing the photoresist 109 together with a portion of the light-emitting functional film 113. At the light-emitting layer forming step, these three steps (i.e., the lift-off process) are repeatedly carried out to form a plurality of kinds of a plurality of the light-emitting layers 62em each of which emits light in a different color.

The light-emitting layer forming step of this example separately forms the red light-emitting layer 62emr, the green light-emitting layer 62emg, and the blue light-emitting layer 62emb. The red light-emitting layer 62emr, the green light-emitting layer 62emg, and the blue light-emitting layer 62emb are formed in any given order. In this example, the red light-emitting layer 62emr, the green light-emitting layer 62emg, and the blue light-emitting layer 62emb are formed in the stated order.

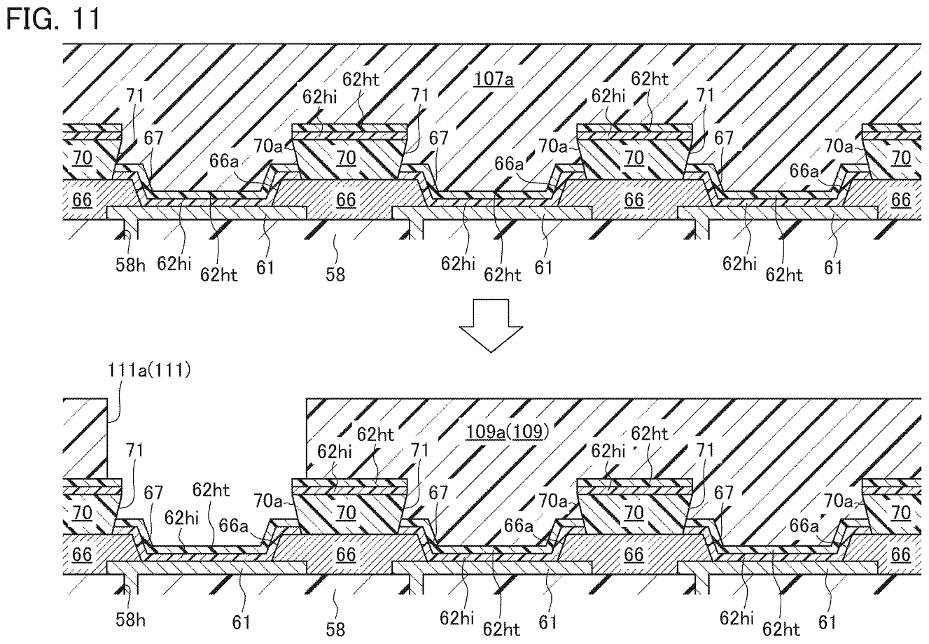

First, as illustrated in a view in the top of FIG. 11, the substrate provided with the hole transport layer 62ht is coated with a photosensitive resin by a known coating technique. Hence, the photosensitive resin forms a coating film 107a. Then, the coating film 107a formed of the photosensitive resin is prebaked, exposed to light, developed, and postbaked. Hence, as illustrated in a view in the bottom of FIG. 11, a first photoresist 109a having a plurality of first openings 111a is formed. A first opening 111a is formed at a position corresponding to an opening 71 provided to the dividing layer 70 and including therein the red light-emitting element 65R.

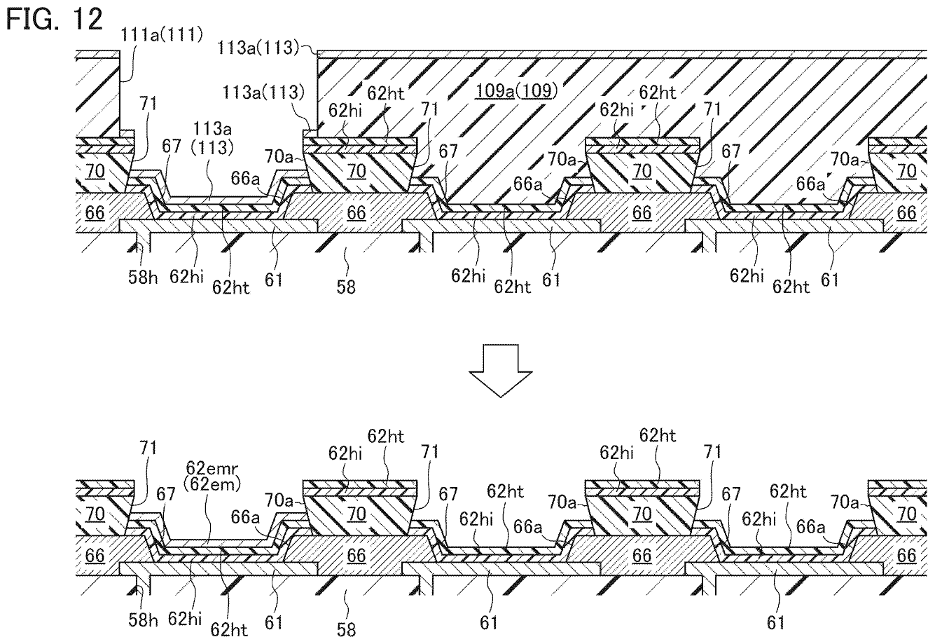

Next, the substrate provided with the first photoresist 109a is coated with a solution by a known coating technique. The solution contains quantum dots forming the red light-emitting layer 62emr. Hence, the solution forms a coating film. Then, the coating film is baked so that the solvent is vaporized. Hence, as illustrated in a view in the top of FIG. 12, a first light-emitting functional film 113a is deposited: in a portion exposed from the first photoresist 109a on the substrate; and on the first photoresist 109a. Here, the portion includes: a portion included in the opening 71 provided to the dividing layer 70 and corresponding to the first opening 111a, and lying from above the first electrode 61 to a peripheral edge portion of the opening 67 of the edge cover 67; and a portion provided above the dividing layer 70 and exposed from the first photoresist 109a.

Here, the first light-emitting functional film 113a provided inside the opening 71 of the dividing layer 70 and the first light-emitting functional film 113a provided above the dividing layer 70 are divided with the level difference of the inner peripheral surface 70a of the opening 71 of the dividing layer 70. After that, the first photoresist 109a is subjected to a resist detaching solution. With the resist detaching solution, the first photoresist 109a is removed together with the first light-emitting functional film 113a on the first photoresist 109a. Hence, as illustrated in a view in the bottom of FIG. 12, the red light-emitting layer 62emr is formed inside a predetermined opening 71 of the dividing layer 70.

Here, the first light-emitting functional film 113a above the dividing layer 70 is delaminated when the first photoresist 109a is removed. The delaminated fragments of the first light-emitting functional film 113a are relatively small. Hence, the delaminated fragments are delaminated from the surface of the substrate (the hole transport layer 62ht in this example) together with the first photoresist 109a, caught in the resist detaching solution, and removed.

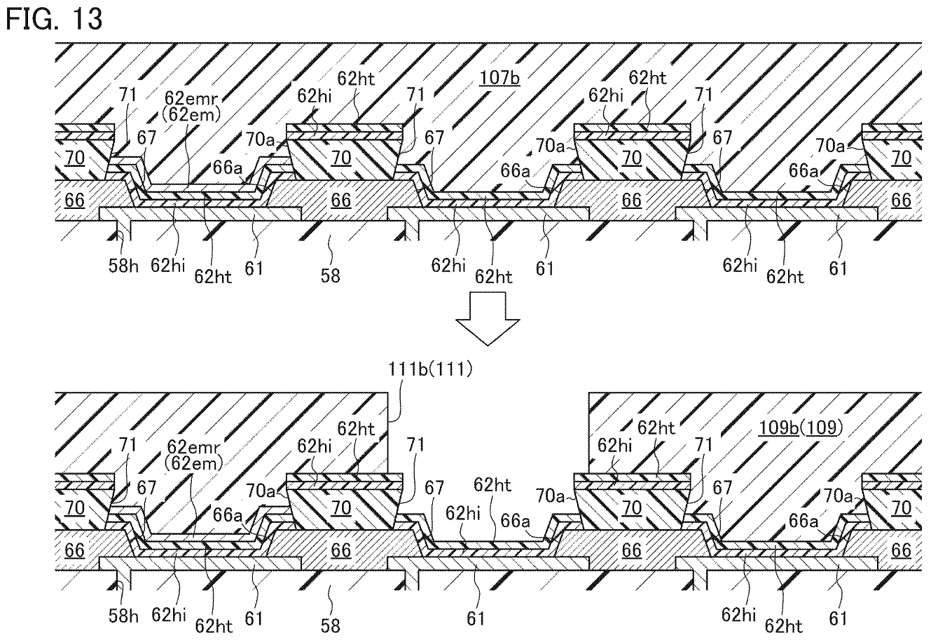

Next, as illustrated in a view in the top of FIG. 13, the substrate provided with the red light-emitting layer 62emr is coated with a photosensitive resin by a known coating technique. Hence, the photosensitive resin forms a coating film 107b. Then, the coating film 107b formed of the photosensitive resin is prebaked, exposed to light, developed, and postbaked. Hence, as illustrated in a view in the bottom of FIG. 13, a second photoresist 109b having a plurality of second openings 111b is formed. A second opening 111b is formed at a position corresponding to an opening 71 provided to the dividing layer 70 and including therein the green light-emitting element 65G.

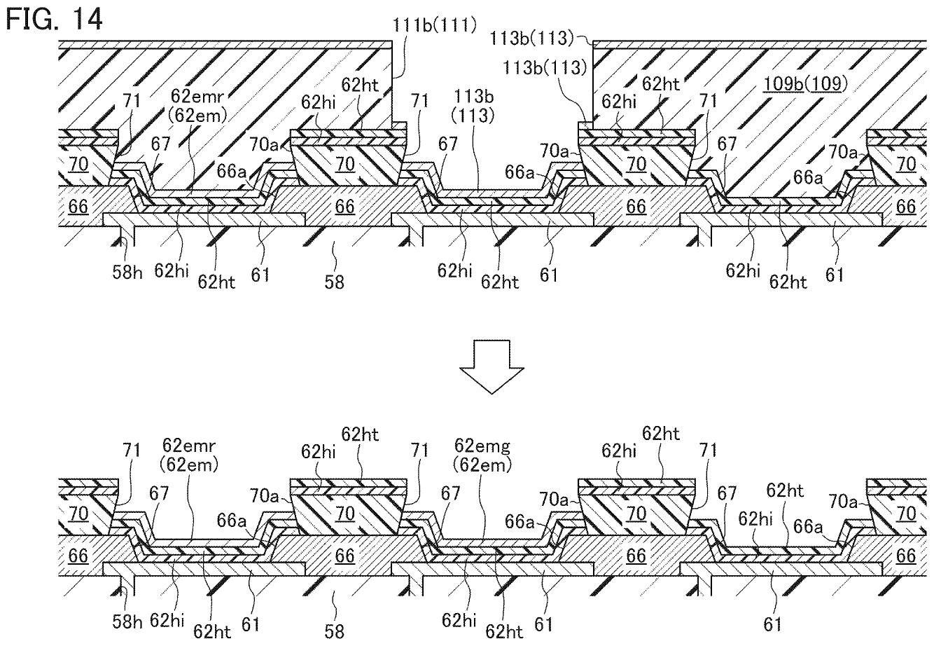

Next, the substrate provided with the second photoresist 109b is coated with a solution by a known coating technique. The solution contains quantum dots forming the green light-emitting layer 62emg. Hence, the solution forms a coating film. Then, the coating film is baked so that the solvent is vaporized. Hence, as illustrated in a view in the top of FIG. 14, a second light-emitting functional film 113b is formed: in a portion exposed from the second photoresist 109b on the substrate; and on the second photoresist 109b. Here, the portion includes: a portion included in the opening 71 provided to the dividing layer 70 and corresponding to the second opening 111b, and lying from above the first electrode 61 to a peripheral edge portion of the opening 67 of the edge cover 66; and a portion provided above the dividing layer 70 and exposed from the second photoresist 109b.

Here, the second light-emitting functional film 113b provided inside the opening 71 of the dividing layer 70 and the second light-emitting functional film 113b provided above the dividing layer 70 are divided with the level difference of the inner peripheral surface 70a of the opening 71 of the dividing layer 70. After that, the second photoresist 109b is subjected to a resist detaching solution. With the resist detaching solution, the second photoresist 109b is removed together with the second light-emitting functional film 113b on the second photoresist 109b. Hence, as illustrated in a view in the bottom of FIG. 14, the green light-emitting layer 62emg is formed inside a predetermined opening 71 of the dividing layer 70.

Here, the second light-emitting functional film 113b above the dividing layer 70 is delaminated when the second photoresist 109b is removed. The delaminated fragments of the second light-emitting functional film 113b are relatively small. Hence, the delaminated fragments are delaminated from the surface of the substrate (the hole transport layer 62ht in this example) together with the second photoresist 109b, caught in the resist detaching solution, and removed.

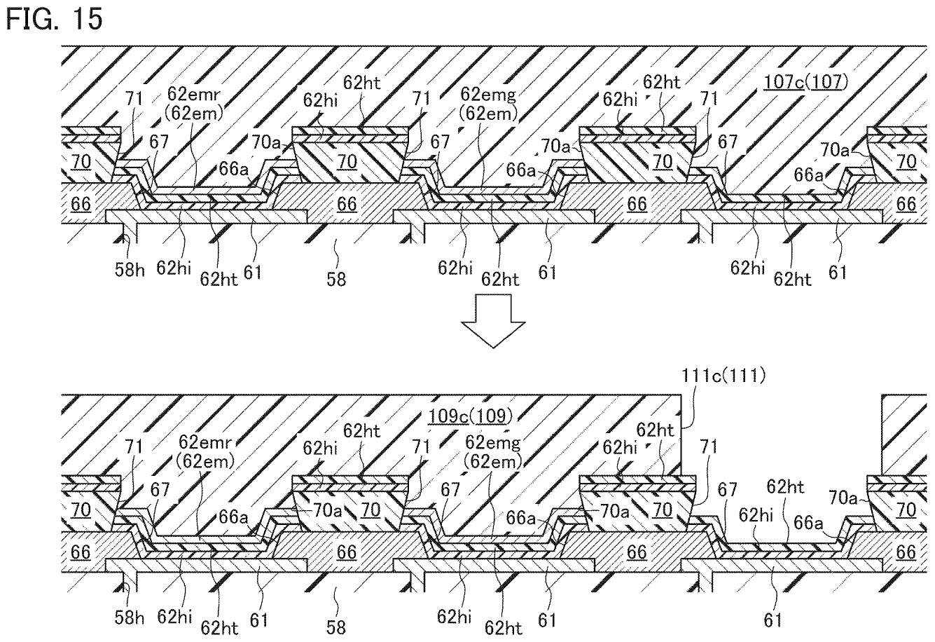

After that, as illustrated in a view in the top of FIG. 15, the substrate provided with the green light-emitting layer 62emg is coated with a photosensitive resin by a known coating technique. Hence, the photosensitive resin forms a coating film 107c. Then, the coating film 107c formed of the photosensitive resin is prebaked, exposed to light, developed, and postbaked. Hence, as illustrated in a view in the bottom of FIG. 15, a third photoresist 109c having a plurality of third openings 111c is formed. A third opening 111c is formed at a position corresponding to an opening 71 provided to the dividing layer 70 and including therein the blue light-emitting element 65B.

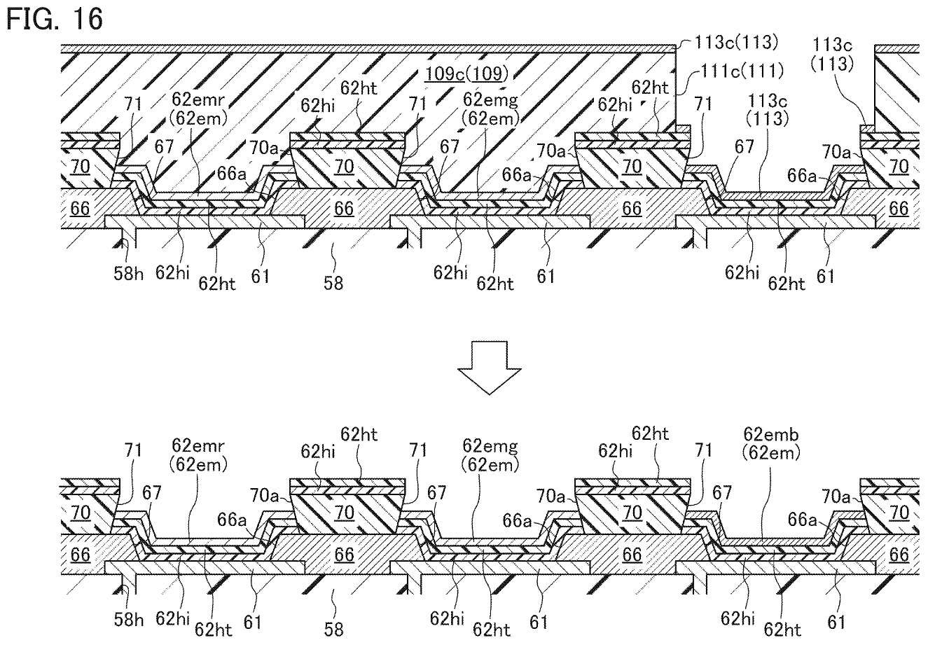

Next, the substrate provided with the third photoresist 109c is coated with a solution by a known coating technique. The solution contains quantum dots forming the blue light-emitting layer 62emb. Hence, the solution forms a coating film. Then, the coating film is baked so that the solvent is vaporized. Hence, as illustrated in a view in the top of FIG. 16, a third light-emitting functional film 113c is formed: in a portion exposed from the third photoresist 109c on the substrate; and on the third photoresist 109c. Here, the portion includes: a portion included in the opening 71 provided to the dividing layer 70 and corresponding to the third opening 111c, and lying from above the first electrode 61 to a peripheral edge portion of the opening 67 of the edge cover 66; and a portion provided above the dividing layer 70 and exposed from the third photoresist 109c.

Here, the third light-emitting functional film 113c provided inside the opening 71 of the dividing layer 70 and the third light-emitting functional film 113c provided above the dividing layer 70 are divided with the level difference of the inner peripheral surface 70a of the opening 71 of the dividing layer 70. After that, the third photoresist 109c is subjected to a resist detaching solution. With the resist detaching solution, the third photoresist 109c is removed together with the third light-emitting functional film 113c on the third photoresist 109c. Hence, as illustrated in a view in the bottom of FIG. 16, the blue light-emitting layer 62emb is formed inside a predetermined opening 71 of the dividing layer 70.

Here, the third light-emitting functional film 113c above the dividing layer 70 is delaminated when the third photoresist 109c is removed. The delaminated fragments of the third light-emitting functional film 113c are relatively small. Hence, the delaminated fragments are delaminated from the surface of the substrate (the hole transport layer 62ht in this example) together with the third photoresist 109c, caught in the resist detaching solution, and removed.

In the process of forming the light-emitting layer 62em, an alkali developing solution is used as a developing solution in the development processing for forming the first to third photoresists 109a, 109b, and 109c. That is, after the exposure to light, the coating films 107a, 107b, and 107c formed of a photosensitive resin are immersed in the developing solution so that unnecessary portions of the coating films 107a, 107b, and 107c; specifically, portions for forming the first opening 111a, the second opening 111b, and the third opening 111c, are removed. Here, the hole transport layer 62ht and the hole injection layer 62hi formed in advance are subjected to the developing solution. However, the hole transport layer 62ht and the hole injection layer 62hi of this example are resistant to the alkali developing solution. Such a feature reduces damage caused by the developing solution.

### Upper Functional Layer Forming Step

The upper functional layer forming step is a step of forming a functional layer included in the EL layer 62 and provided above the light-emitting layer 62em; that is, in this example, a step of forming the electron transport layer 62et.

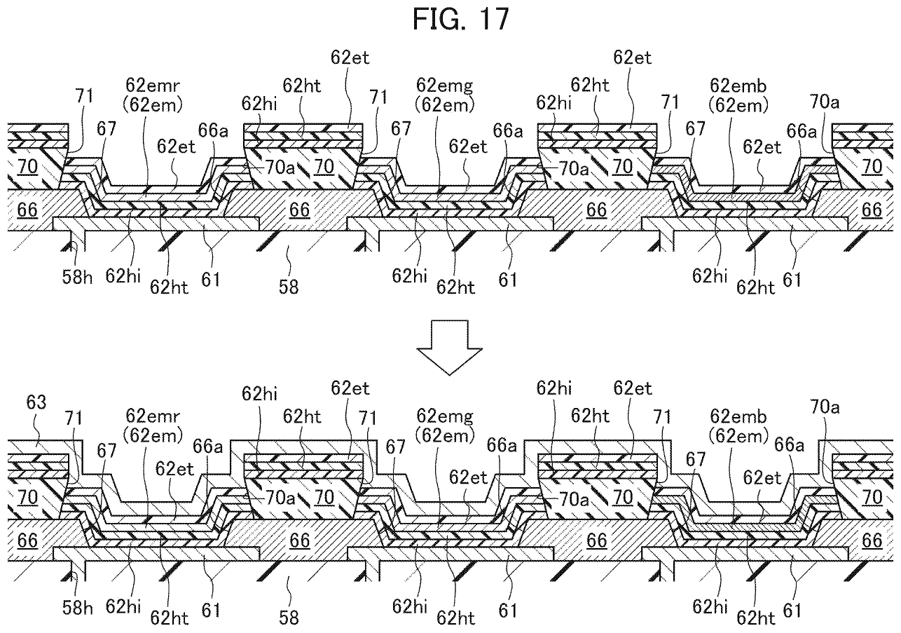

The upper functional layer forming step is carried out as follows. First, the substrate provided with the light-emitting layer 62em is coated with a solution by a known coating technique. The solution contains the above-described compound suitable for the function of transporting electrons. Hence, the solution forms a coating film. Then, the coating film is baked so that the solvent is vaporized. Hence, as illustrated in a view in the top of FIG. 17, the electron transport layer 62et is formed inside each of the openings 71 of the dividing layer 70 and above the dividing layer 70. Specifically, for example, the electron transport layer 62et is formed of either zinc oxide nanoparticles (ZnO-NPs) or magnesium zinc oxide nanoparticle (MgZnO-NPs).

Thus, the EL layer 62 is formed in each of the openings 71 of the dividing layer 70.

### Second Electrode Forming Step

The second electrode forming step is a step of forming the second electrode 63 that serves as a continuous common film across the plurality of subpixels SP. At the second electrode forming step, on the substrate provided with the EL layer 62, at least one conductive film is deposited by, for example, vacuum deposition. The at least one conductive film is selected from: an indium tin oxide film (an ITO film); indium zinc oxide film (an IZO film); a magnesium silver alloy film (a MgAg film); silver (Ag); and a silver-nanowire film (a Ag-NW film). Hence, as illustrated in a view in the bottom of FIG. 17, the second electrode 63 is formed on each of the EL layers 62.

As described above, the light-emitting-element layer 60 is successfully formed. Note that, in addition to the above techniques, known techniques such as vacuum deposition, electron beam deposition, sputtering, inkjet printing, spin coating, and printing can be used for forming the first electrodes 61, the hole injection layer 62hi, the hole transport layer 62ht, the light-emitting layer 62em, the electron transport layer 62et, and the second electrode 63. These techniques are selected, depending on properties of the materials for each of the layers.

### Features of First Embodiment

In the quantum-dot display device 1 according to the first embodiment, the display region DA is provided with the dividing layer 70 having the plurality of openings 71 corresponding to the subpixels SP. The inner peripheral surface 70a of each of the openings 71 of the dividing layer 70 is formed to have a reverse-tapered angled surface so that the opening 71 widens downwards of the dividing layer 70. Then, the light-emitting layer 62em is provided inside the opening 71 of the dividing layer 70. In manufacturing the quantum-dot display device 1, when the light-emitting layer 62em is formed by lift-off, such features can reduce delamination of the light-emitting layer 62em while the photoresist 109 is removed.

Furthermore, when the photoresist 109 is removed in the lift-off process, the light-emitting functional film 113 deposited on an edge portion of the opening 111 of the photoresist 109 is partially delaminated. If the delaminated fragments are relatively large, the delaminated fragments cannot be removed together with the photoresist 109 and might adhere to the light-emitting layer 62em. In this case, a portion, of the light-emitting layer 62em, to which the delaminated fragments adhere does not emit light. As a result, a light-emission characteristic of the quantum-dot light-emitting element 65 deteriorates. Whereas, as to the quantum-dot display device 1 of the first example, even if the light-emitting functional film 113 deposited on an edge portion of the opening 111 of the photoresist 109 is partially delaminated, the delaminated fragments are relatively small. The smaller the delaminated fragments are, the easier the removal of the delaminated fragments is while the photoresist 109 is removed. Such a feature can reduce adhesion of the delaminated fragments to the light-emitting layer 62em.

As to the quantum-dot display device 1 according to the first embodiment, the inner peripheral surface 70a of the opening 71 of the dividing layer 70 is formed to have a reverse-tapered angled surface. In manufacturing the quantum-dot display device 1, when the light-emitting layer 62em is formed by lift-off, such a feature makes it possible to suitably divide the light-emitting functional film 113 with the level difference of the inner peripheral surface 70a of the opening 71 of the dividing layer 70. This is advantageous in reducing delamination of the light-emitting layer 62em.

As to the quantum-dot display device 1 according to the first embodiment, the inner peripheral surface 70a of the opening 71 of the dividing layer 70 is angled so that an angle α, formed inwards the dividing layer 70 with respect to a direction perpendicular to a thickness direction of the dividing layer 70, is within a predetermined angle range of 90 degrees or larger and 130 degrees or smaller. In manufacturing the quantum-dot display device 1, when the light-emitting layer 62em is formed by lift-off, such a feature is advantageous in dividing the light-emitting functional film 113 with the level difference of the inner peripheral surface 70a of the opening 71 of the dividing layer 70.

As to the quantum-dot display device 1 according to the first embodiment, a thickness H of the dividing layer 70 is set larger than a sum of: the total thickness Ta of the hole injection layer 62hi and the hole transport layer 62ht; and three times the thickness Tb of the light-emitting layer 62em. Such a feature makes it possible to suitably divide the light-emitting layer 62em with the level difference of the inner peripheral surface 70a of the opening 71 of the dividing layer 70.

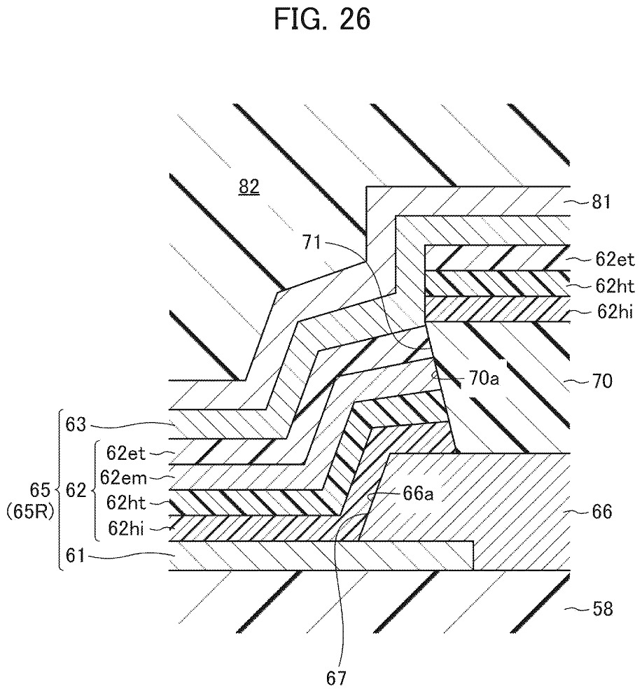

As illustrated in FIG. 26, a thickness of each of the hole injection layer 62hi, the hole transport layer 62ht, the light-emitting layer 62em, and the electron transport layer 62et might be large at an outer peripheral portion along the inner peripheral surface 70a of the opening 71 of the dividing layer 70. Whereas, the thickness H of the dividing layer 70 is set smaller than, or equal to, a value obtained by adding 200 nm to three times a sum of the thicknesses (Ta+Tb+Tc) of the hole injection layer 62hi, the hole transport layer 62ht, the light-emitting layer 62em, and the electron transport layer 62et. Even if a thickness of each of the hole injection layer 62hi, the hole transport layer 62ht, the light-emitting layer 62em, and the electron transport layer 62et is approximately three times as large as a center portion of the EL layer 62 in an outer peripheral portion along the inner peripheral surface 70a of the opening 71 of the dividing layer 70, such a feature allows the level difference provided on the dividing layer 70 to divide the light-emitting layer 62em and leave the second electrode 63 undivided.

As to the quantum-dot display device 1 according to the first embodiment, the hole injection layer 62hi contains nickel oxide nanoparticles (NiO-NPs). The nickel oxide nanoparticles are resistant to an alkali developing solution. Thus, in manufacturing the quantum-dot display device 1, when an alkali developing solution is used for development processing of the photoresist 109 in the lift-off process for forming the light-emitting layer 62em, the nickel oxide nanoparticles are suitable as a material for the hole injection layer 62hi.

In the method for manufacturing the quantum-dot display device 1 according to the first embodiment, at the dividing layer forming step, the dividing layer 70 is formed on the substrate to have the plurality of openings 71 corresponding to the subpixels SP. The inner peripheral surface 70a of each of the openings 71 of the dividing layer 70 is formed to have a reverse-tapered angled surface so that the opening 71 widens downwards of the dividing layer 70. Then, at the light-emitting layer forming step, the lift-off process is utilized to form the light-emitting layer 62em in the opening 71 of the dividing layer 70. The lift-off process involves: forming on the dividing layer 70 the photoresist 109 having a predetermined opening 111; depositing the light-emitting functional film 113 in a portion exposed from the photoresist 109 on the substrate, and on the photoresist 109; and, after that, removing the photoresist 109 with a resist detaching solution together with the light-emitting functional film 113 on the photoresist 109. Here, the deposited light-emitting functional film 113 is divided with the level difference of the inner peripheral surface 70a of the opening 71 of the dividing layer 70. Then, the light-emitting functional film 113 provided inside the opening 71 of the dividing layer 70 forms the light-emitting layer 62em. Such a feature can reduce the risk that the light-emitting layer 62em is delaminated while the photoresist 109 is removed.

Furthermore, when the photoresist 109 is removed in the lift-off process, the light-emitting functional film 113 deposited on an edge portion of the opening 111 of the photoresist 109 is partially delaminated. If the delaminated fragments are relatively large, the delaminated fragments cannot be removed together with the photoresist 109 and might adhere to the light-emitting layer 62em. In this case, a portion, of the light-emitting layer 62em, to which the delaminated fragments adhere does not emit light. As a result, a light-emission characteristic of the quantum-dot light-emitting element 65 deteriorates. Whereas, as to the method for manufacturing the quantum-dot display device 1, even if the light-emitting functional film 113 deposited on an edge portion of the opening 111 of the photoresist 109 is partially delaminated, the delaminated fragments are relatively small. The smaller the delaminated fragments are, the easier the removal of the delaminated fragments is while the photoresist 109 is removed. Such a feature can reduce adhesion of the delaminated fragments to the light-emitting layer 62em.

As to the method for manufacturing the quantum-dot display device 1 according to the first embodiment, at the lower functional layer forming step, the hole injection layer 62hi is formed of nickel oxide nanoparticles (NiO-NPs). Then, at the light-emitting layer forming step, when the photoresist 109 is formed in the lift-off process, development processing is carried out using an alkali developing solution. The nickel oxide nanoparticles are resistant to the alkali developing solution. Such a feature can reduce the risk of damage to the hole injection layer 62hi when the hole injection layer 62hi is subjected to the alkali developing solution at the light-emitting layer forming step.

### Second Embodiment

The quantum-dot display device 1 according to a second embodiment is different from that according to the first embodiment described above as to the configuration of the dividing layer 70. Note that the quantum-dot display device 1 of the second embodiment is the same in configuration as that of the first embodiment except for the difference in the configuration of the dividing layer 70.

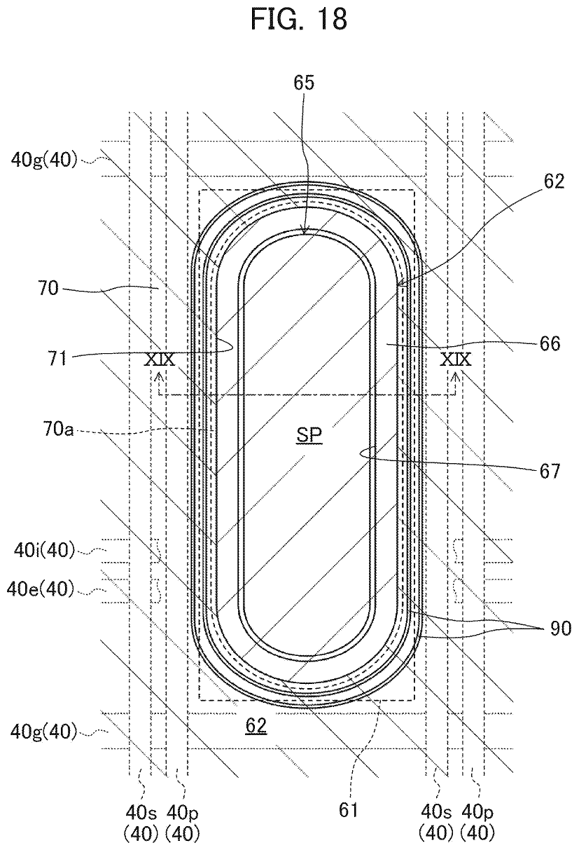

As illustrated in FIG. 18, in the quantum-dot display device 1 according to the second embodiment, a surface on a peripheral edge portion of the opening 71 of the dividing layer 70 has a groove 90 shaped into a loop and formed to extend along the peripheral edge of the opening 71. The groove 90 includes a plurality of grooves 90 provided for each of the openings 71 of the dividing layer 70 and extending in parallel with one another. FIG. 18 shows an example in which two grooves 90 are formed for each opening 71. Alternatively, three or more grooves 90 may be formed, or only one groove 90 may be formed.

Each groove 90 has a depth Dg set to keep the dividing layer 70 from breaking toward the inner peripheral surface 70a and, simultaneously, to contribute to division of the light-emitting functional film 113. Specifically, if the total thickness of the hole injection layer 62hi and the hole transport layer 62ht in a center portion of the EL layer 62 is set to Ta [nm], and the thickness of the dividing layer 70 is set to H [nm], the depth Dg [nm] of the groove 90 is set to satisfy a relational expression (Expression 2) below.

$$Ta < Dg < H / 2. \qquad ( Expression 2 )$$

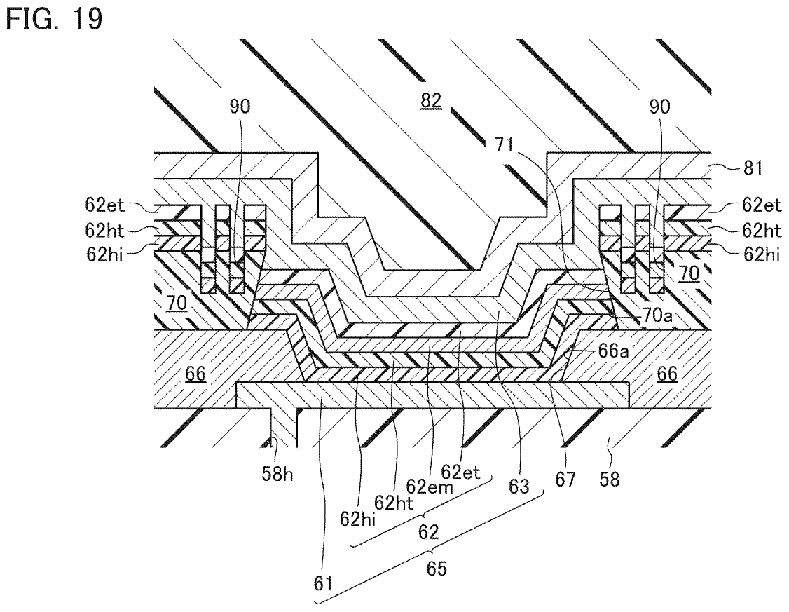

As illustrated in FIG. 19, the groove 90 contains: the hole injection layer 62hi, the hole transport layer 62ht, and the electron transport layer 62et. Each of the hole injection layer 62hi, the hole transport layer 62ht, and the electron transport layer 62et does not have to be left in the groove 90. The second electrode 63 covers either the groove 90 or at least one of such functional layers as the hole injection layer 62hi, the hole transport layer 62ht, or the electron transport layer 62et, and extends to the display region DA.

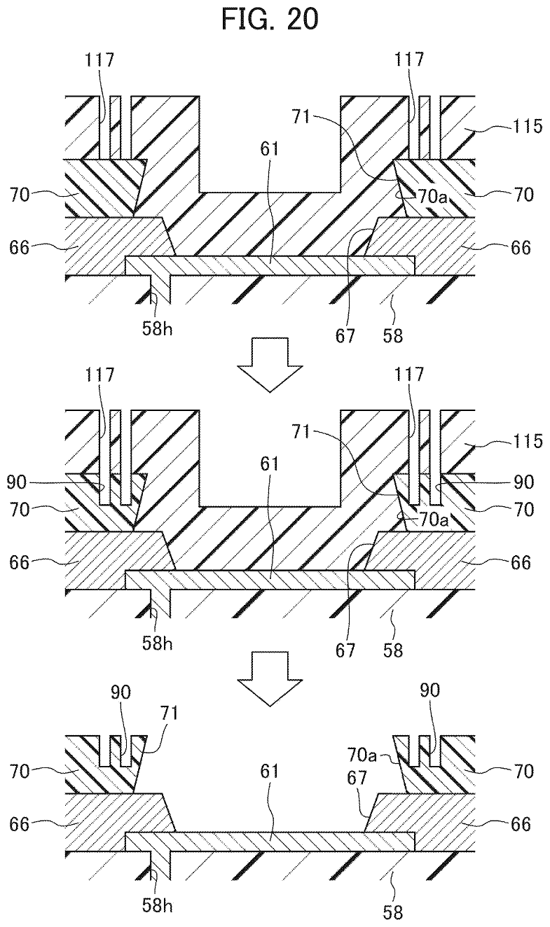

In order to manufacture the quantum-dot display device 1 according to the second embodiment, the dividing layer 70 is formed at the dividing layer forming step. After that, the dividing layer 70 is coated with a photosensitive resin by a known coating technique. Hence, the photosensitive resin forms a coating film. Then, the coating film formed of the photosensitive resin is prebaked, exposed to light, developed, and postbaked. Hence, as illustrated in a view in the top of FIG. 20, a fourth photoresist 115 is formed to have a plurality of patterning openings 117. The patterning openings 117 are formed at positions corresponding to the grooves 90 formed in the dividing layer 70.

Next, using the fourth photoresist 115 as a mask, the dividing layer 70 is dry-etched. Then, as illustrated in a view in the middle of FIG. 20, portions of the dividing layer 70 corresponding to the respective patterning openings 117 are partially removed from the surface. Hence, the grooves 90 are formed in the dividing layer 70. After that, as illustrated in a view in the bottom of FIG. 20, the fourth photoresist 115 is subjected to a resist detaching solution and removed.

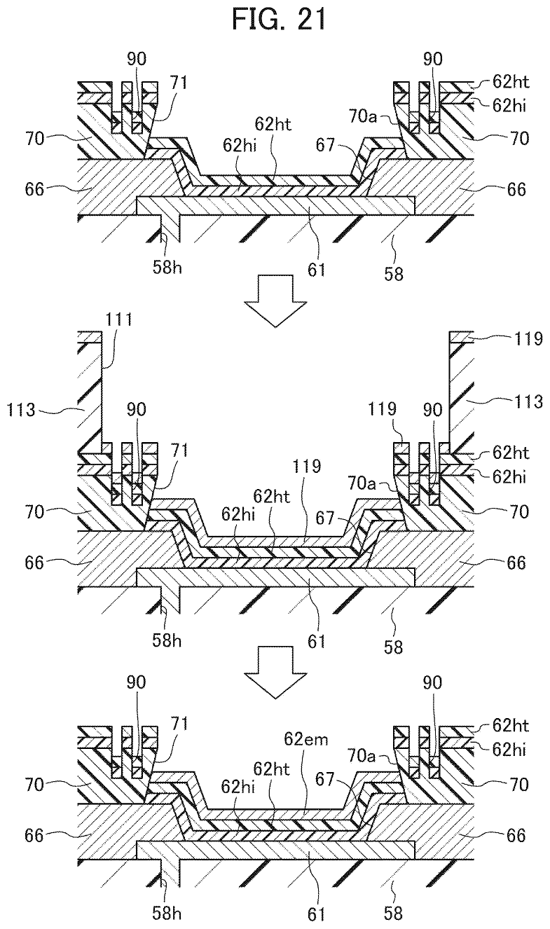

As can be seen, the grooves 90 are formed in the dividing layer 70. Hence, as illustrated in a view in the top of FIG. 21, when the hole injection layer 62hi and the hole transport layer 62ht are formed at the lower functional layer forming step, portions of the hole injection layer 62hi and the hole transport layer 62ht provided above the dividing layer 70 enter the grooves 90. The grooves 90 have the depth Dg that satisfies the above relational expression (Expression 2). The depth Dg is sufficiently deep for accommodating the portions of the hole injection layer 62hi and the hole transport layer 62ht.

Next, when the light-emitting layer 62em is formed by a lift-off process at the light-emitting layer forming step, as illustrated in a view in the middle of FIG. 21, a portion of the light-emitting functional film 113 provided above the dividing layer 70 also enters the grooves 90. Then, the light-emitting functional film 113 above the dividing layer 70 is divided and subdivided with the grooves 90. After that, as illustrated in a view in the bottom of FIG. 21, photoresist 109 is subjected to a resist detaching solution. The light-emitting functional film 113 above the dividing layer 70 is subdivided, and thus easily caught in the resist detaching solution and removed.

### Features of Second Embodiment

In the quantum-dot display device 1 according to the second embodiment, a surface on a peripheral edge portion of the opening 71 of the dividing layer 70 has a groove 90 formed to extend along the peripheral edge of the opening 71. In manufacturing the quantum-dot display device 1, when the light-emitting layer 62em is formed by lift-off, the groove 90 can divide the light-emitting functional film 113 above the dividing layer 70. Hence, when the light-emitting functional film 113 is divided, the dividing layer 70 can function more effectively.

As to the quantum-dot display device 1 according to the second embodiment, a plurality of the grooves 90 is provided to extend in parallel with one another for each of the openings 71 of the dividing layer 70. Such a feature makes it possible to divide the light-emitting functional film 113 above the dividing layer 70 at two or more positions. Hence, even if the light-emitting functional film 113 above the dividing layer 70 is delaminated, the delaminated fragments can be relatively small. This is advantageous in reducing delamination of the light-emitting layer 62em and reattachment of the delaminated fragments to the light-emitting layer 62em.

### Third Embodiment

The quantum-dot display device 1 according to a third embodiment is different from that according to the first embodiment as to configurations of the hole injection layer 62hi and the hole transport layer 62ht and a design in height of the dividing layer 70. Note that the quantum-dot display device 1 of the third embodiment is the same in configuration as that of the first embodiment except for the differences in the configurations of the hole injection layer 62hi and the hole transport layer 62ht and the design in height of the dividing layer 70.

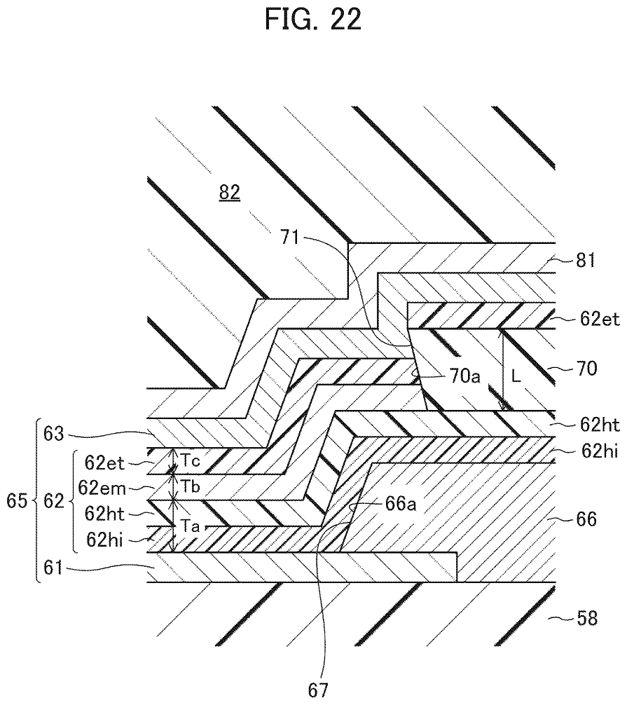

As illustrated in FIG. 22, as to the quantum-dot display device 1 according to the second embodiment, each of the hole injection layer 62hi and the hole transport layer 62ht is provided to serve as a continuous common film across the plurality of subpixels SP. Both the hole injection layer 62hi and the hole transport layer 62ht cover the plurality of first electrodes 61 and the edge cover 66, and extend to the entire display region DA. Then, the dividing layer 70 is provided on the hole transport layer 62ht. The dividing layer 70 overlaps with the edge cover 66 through the hole injection layer 62hi and the hole transport layer 62ht.

Similar to the first embodiment, a thickness of the dividing layer 70 is set so that the level difference of the inner peripheral surface 70a of the opening 71 divides the light-emitting layer 62em and leaves the second electrode 63 undivided. Specifically, if the thickness of the light-emitting layer 62em in a center portion of the EL layer 62 is set to Tb [nm], and the thickness of the electron transport layer 62et is set to Tc [nm], the thickness H [nm] of the dividing layer 70 is set to satisfy a relational expression (Expression 3) below.

$$3 Tb < H \leq 200 + 3 ( Tb + Tc ) \qquad ( Expression 3 )$$

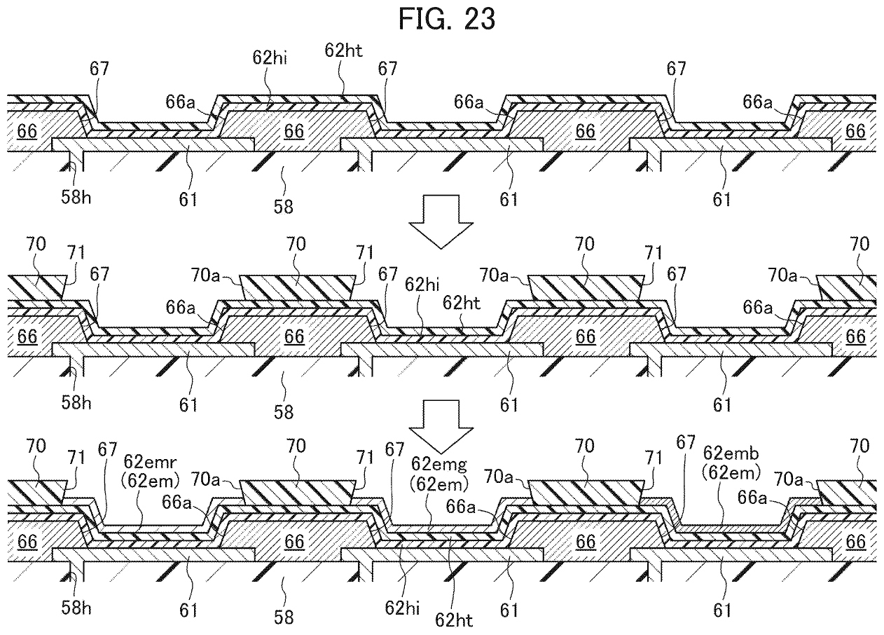

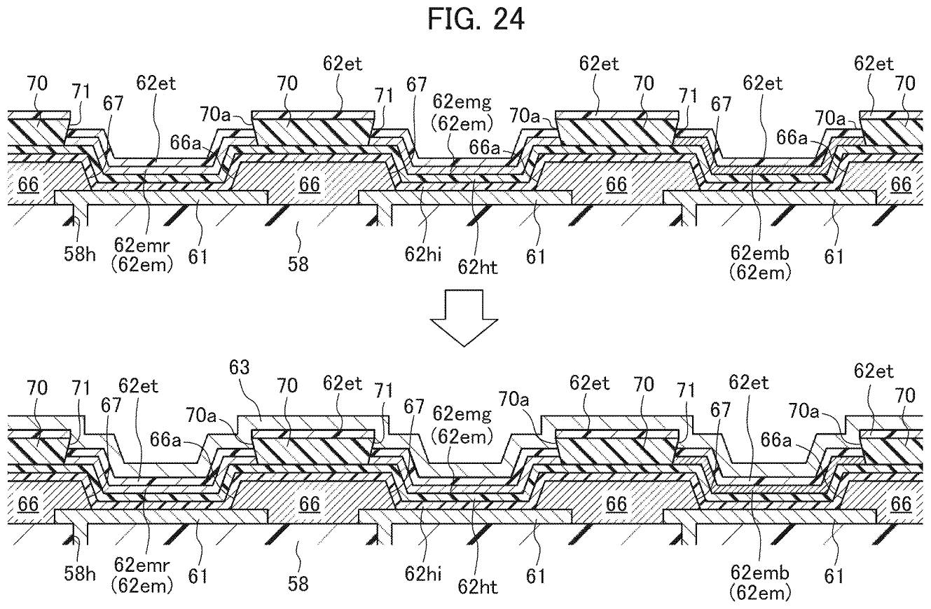

In order to manufacture the quantum-dot display device 1 according to the third embodiment, the lower functional layer forming step may succeed the edge cover forming step and precede the dividing layer forming step. Specifically, as illustrated in a view in the top of FIG. 23, on the substrate provided with the edge cover 66, the hole injection layer 62hi and the hole transport layer 62ht are formed in the stated order. Then, as illustrated in a view in the middle of FIG. 23, the dividing layer 70 is formed on the hole transport layer 62ht. Next, as illustrated in a view in the bottom of FIG. 23, the light-emitting layer 62em is formed by lift-off. After that, as illustrated in FIG. 24, the electron transport layer 62et and the second electrode 63 are formed in the stated order.

### Features of Third Embodiment

As to the quantum-dot display device 1 according to the third embodiment, the thickness H of the dividing layer 70 is set larger than the thickness of three times the thickness Tb of the light-emitting layer 62em. Such a feature makes it possible to suitably divide the light-emitting layer 62em with the level difference of the inner peripheral surface 70a of the opening 71 of the dividing layer 70. Furthermore, the thickness H of the dividing layer 70 is set smaller than, or equal to, a value obtained by adding 200 nm to three times a sum of the thicknesses (Tb+Tc) of the light-emitting layer 62em and the electron transport layer 62et. Even if a thickness of each of the light-emitting layer 62em and the electron transport layer 62et is three times as large as a center portion of the EL layer 62 in an outer peripheral portion along the inner peripheral surface 70a of the opening 71 of the dividing layer 70, such a feature allows the level difference provided on the dividing layer 70 to divide the light-emitting layer 62em and leave the second electrode 63 undivided.

### Other Embodiments

In the first to third embodiments above, the inner peripheral surface 70a of the opening 71 of the dividing layer 70 is formed to have a reverse-tapered angled surface. However, the embodiments shall not be limited to such a configuration. As illustrated in FG. 25, the inner peripheral surface 70a of the opening 71 of the dividing layer 70 may be formed to have an upright surface standing upright in the thickness direction of the dividing layer 70. In manufacturing the quantum-dot display device 1, when the light-emitting layer 62em is formed by lift-off, such a feature also allows the level difference of the inner peripheral surface 70a of the opening 71 of the dividing layer 70 to divide the deposited light-emitting functional film 113 and makes it possible to reduce delamination of the light-emitting layer 62em while the photoresist 109 is removed.

In the first to third embodiments, in the exposure processing for forming the dividing layer 70, a multitone mask such as a halftone mask or a graytone mask may be used as the photomask to adjust the exposure doze of the coating film 105 formed of a photosensitive resin. In short, when a negative photosensitive resin is used for forming the dividing layer 70, an exposure dose of a portion included in the photosensitive-resin coating film 105 and forming an outer peripheral surface of the dividing layer 70 is set lower than an exposure dose of another portion of the dividing layer 70.

In the first to third embodiments, each of the pixels PX includes subpixels Sp presenting, but not limited to, three colors. The colors of the subpixels SP included in each pixel PX are not limited to three colors. The colors may be four or more colors. Furthermore, the subpixels SP included in each pixel PX and presenting three colors are arranged in, but not limited to, stripes. The plurality of subpixels SP may be arranged in another manner such as PenTile Matrix.

In the first to third embodiments, each first electrode 61 and the second electrode 63 are respectively, but not limited to, a positive electrode and a negative electrode. As to the quantum-dot display device 1, the first electrode 61 may function as a negative electrode and the second electrode 63 may function as a positive electrode. In this case, the EL layer 62 has an inverted multilayer structure.

That is, citing the multilayer structure of the EL layer 62 in the first embodiment as an example, the electron transport layer 62et, light-emitting layer 62em, the hole transport layer 62ht, and the hole injection layer 62hi are stacked on top of another in the stated order. In this case, the electron transport layer 62et corresponds to the lower functional layer. Furthermore, the electrons correspond to the first carriers. Moreover, the hole transport layer 62ht and the hole injection layer 62hi correspond to the upper functional layers. In addition, the holes correspond to the second carriers.

In the first to third embodiments, the EL layer 62 has, but not limited to, a four-layer structure including the hole injection layer 62hi, the hole transport layer 62ht, the light-emitting layer 62em, and the electron transport layer 62et. The EL layer 62 may have a five-layer structure further including an electron injection layer on the electron transport layer 62et. Moreover, the EL layer 62 may have a three-layer structure omitting either the hole injection layer 62hi or the hole transport layer 62ht. If the EL layer 62 includes a plurality of functional layers, the EL layer 62 may have any given multilayer structure. Furthermore, the EL layer 62 may include the light-emitting layer 62em alone.

In the first to third embodiments, the substrate of the quantum-dot display device 1 is, but not limited to, the substrate layer 10. The substrate may be formed of any given material. Examples of the substrate include a plastic substrate formed of polyethylene terephthalate (PET) and a glass substrate.

In the first to third embodiments, the example of the display device according to the present disclosure is, but not limited to, the quantum-dot display device 1. Techniques of the present disclosure are applicable to another display device including a plurality of light-emitting elements. The display device is, for example, an organic EL display device including an organic EL element having a light-emitting layer formed of an organic material.

As can be seen, preferred embodiments have been described as examples of the techniques of the present disclosure. However, the techniques of the present disclosure shall not be limited to the above examples. The techniques are applicable to embodiments with appropriate modifications such as changes, substitutions, additions, and omissions of features. It will be understood by those skilled in the art that various modifications can be made to the above first to third embodiments without departing from the scope of the present disclosure, and that such modifications fall within the scope of the present disclosure.

### INDUSTRIAL APPLICABILITY

As described above, the present disclosure is useful for a display device and a method for manufacturing the display device.

1-19. (canceled)

20: A display device, comprising
a plurality of light-emitting elements provided to correspond to a plurality of subpixels included in a display region,
wherein each of the plurality of light-emitting elements has a light-emitting layer individually separated,
the display region is provided with a dividing layer having a plurality of openings corresponding to the subpixels,
each of the openings of the dividing layer is provided with an inner peripheral surface formed to have either an upright surface standing upright in a thickness direction of the dividing layer, or a reverse-tapered angled surface so that the opening widens downwards of the dividing layer,
the light-emitting layer is provided inside the opening of the dividing layer,
each of the plurality of light-emitting elements has: a first electrode; an electroluminescent layer including the light-emitting layer provided on the first electrode; and a second electrode overlapping with the first electrode through the electroluminescent layer,
the first electrode is individually separated,
the second electrode is provided to serve as a continuous common film across the plurality of subpixels,
the electroluminescent layer further includes:
a lower functional layer provided below the light-emitting layer and configured to move a first carrier from the first electrode to the light-emitting layer; and
an upper functional layer provided above the light-emitting layer and configured to move a second carrier from the second electrode to the light-emitting layer,
wherein one of the first carrier or the second carrier is an electron and another one of the first carrier or the second carrier is a hole,
the lower functional layer is provided to serve as a continuous common film across the plurality of subpixels, and
the dividing layer is provided on the lower functional layer.

21: The display device according to claim 20,
wherein the inner peripheral surface of each of the openings of the dividing layer is formed to have the reverse-tapered angled surface.

22: The display device according to claim 21,
wherein the inner peripheral surface of each of the openings of the dividing layer is angled so that an angle, formed inwards the dividing layer with respect to a direction perpendicular to a thickness direction of the dividing layer, is within a predetermined angle range of greater than, or equal to, 90 degrees and smaller than, or equal to, 130 degrees.

23: The display device according to claim 20,
wherein a surface on a peripheral edge portion of the opening of the dividing layer has a groove formed to extend along a peripheral edge of the opening.

24: The display device according to claim 23,
wherein the groove includes a plurality of grooves provided for each of the openings of the dividing layer and extending in parallel with one another.

25: The display device according to claim 20,
wherein the display region is provided with an edge cover: having a plurality of openings corresponding the subpixels; and provided to cover an outer edge of the first electrode,
the dividing layer is provided on the edge cover, and
each of the openings of the dividing layer is formed to contain one of the openings of the edge cover in a plan view.

26: The display device according to claim 20,
wherein the lower functional layer is: provided on the dividing layer, and in each of the openings of the dividing layer; and divided with a level difference of the inner peripheral surface of the opening of the dividing layer.

27: The display device according to claim 26,
wherein, if a thickness of the lower functional layer in a center portion of the electroluminescent layer is set to Ta [nm], a thickness of the light-emitting layer is set to Tb [nm], and a thickness of the upper functional layer is set to Tc [nm], a thickness H [nm] of the dividing layer is set to satisfy a relational expression below:
$$Ta + 3 Tb < H \leq 3 ( Ta + Tb + Tc ) + 200 .$$

28: The display device according to claim 20,
wherein, if a thickness of the light-emitting layer in a center portion of the electroluminescent layer is set to Tb [nm], and a thickness of the upper functional layer is set to Tc [nm], a thickness H [nm] of the dividing layer is set to satisfy a relational expression below:
$$3 Tb < H \leq 200 + 3 ( Tb + Tc ) .$$

29: The display device according to claim 20,
wherein the first electrode functions as a positive electrode,
the second electrode functions as a negative electrode, and
the lower functional layer contains nickel oxide nanoparticles.

30: The display device according claim 20,
wherein the plurality of light-emitting elements includes a plurality of kinds of light-emitting elements each of which emits light in a different color.

31: The display device according to claim 30,
wherein the plurality of kinds of light-emitting elements include: a red light-emitting element having the light-emitting layer that emits light in red; a green light-emitting element having the light-emitting layer that emits light in green; and a blue light-emitting element having the light-emitting layer that emits light in blue.

32: The display device according to claim 20,
wherein the light-emitting elements are quantum-dot light-emitting elements each having the light-emitting layer containing quantum dots.

33: A method for manufacturing a display device in which a plurality of light-emitting elements, each of which has a light-emitting layer individually separated, is provided to correspond to a plurality of subpixels included in a display region, the method comprising:
a dividing layer forming step of forming, on a substrate, a dividing layer having a plurality of openings corresponding to the subpixels, each of the openings being provided with an inner peripheral surface formed to have either an upright surface standing upright in a thickness direction of the dividing layer, or a reverse-tapered angled surface so that the opening widens downwards of the dividing layer;
a light-emitting layer forming step of forming, on a substrate provided with the dividing layer, a photoresist having an opening at a predetermined position, depositing a light-emitting functional film on a portion exposed from the photoresist on the substrate and on the photoresist, and removing the photoresist together with the light-emitting functional film on the photoresist using a resist detaching solution, in order to form the light-emitting layer inside the opening of the dividing layer;
a first electrode forming step of forming, on the substrate, a plurality of first electrodes individually separated from one another;
an electroluminescent layer forming step of forming an electroluminescent layer on the plurality of first electrodes; and
a second electrode forming step of forming, on the electroluminescent layer, a second electrode that serves as a continuous common film across the plurality of subpixels,
wherein the electroluminescent layer forming step includes: a lower functional layer forming step of forming a lower functional layer; and the light-emitting layer forming step of forming the light-emitting layer on the lower functional layer,
at the lower functional layer forming step, the lower functional layer is formed of nickel oxide nanoparticles, and
at the light-emitting layer forming step, when the photoresist is formed, development processing is carried out using an alkali developing solution.

34: The method for manufacturing the display device according to claim 33,
wherein, at the light-emitting layer forming step, a step of forming the photoresist, a step of depositing the light-emitting functional film, and a step of removing the photoresist together with a portion of the light-emitting functional film are repeatedly carried out to form a plurality of kinds of a plurality of the light-emitting layers each of which emits light in a different color.

35: A display device, comprising
a plurality of light-emitting elements provided to correspond to a plurality of subpixels included in a display region,
wherein each of the plurality of light-emitting elements has a light-emitting layer individually separated,
the display region is provided with a dividing layer having a plurality of openings corresponding to the subpixels,
each of the openings of the dividing layer is provided with an inner peripheral surface formed to have either an upright surface standing upright in a thickness direction of the dividing layer, or a reverse-tapered angled surface so that the opening widens downwards of the dividing layer,
the light-emitting layer is provided inside the opening of the dividing layer,
each of the plurality of light-emitting elements has: a first electrode; an electroluminescent layer including the light-emitting layer provided on the first electrode; and a second electrode overlapping with the first electrode through the electroluminescent layer,
the first electrode is individually separated,
the second electrode is provided to serve as a continuous common film across the plurality of subpixels,
the electroluminescent layer further includes:
a lower functional layer provided below the light-emitting layer and configured to move a first carrier from the first electrode to the light-emitting layer; and
an upper functional layer provided above the light-emitting layer and configured to move a second carrier from the second electrode to the light-emitting layer,
wherein one of the first carrier or the second carrier is an electron and another one of the first carrier or the second carrier is a hole
the first electrode functions as a positive electrode,
the second electrode functions as a negative electrode, and
the lower functional layer contains nickel oxide nanoparticles.

36: The display device according to claim 35,
wherein the inner peripheral surface of each of the openings of the dividing layer is formed to have the reverse-tapered angled surface.

37: The display device according to claim 36,
wherein the inner peripheral surface of each of the openings of the dividing layer is angled so that an angle, formed inwards the dividing layer with respect to a direction perpendicular to a thickness direction of the dividing layer, is within a predetermined angle range of greater than, or equal to, 90 degrees and smaller than, or equal to, 130 degrees.

38: The display device according to claim 35,
wherein a surface on a peripheral edge portion of the opening of the dividing layer has a groove formed to extend along a peripheral edge of the opening.

39: The display device according to claim 38,
wherein the groove includes a plurality of grooves provided for each of the openings of the dividing layer and extending in parallel with one another.
